(19) United States
(12) Patent Application Publication
(10) Pub. No.: US 2024/0134278 A1
(43) Pub. Date: Apr. 25, 2024

(54) SURFACE MODIFIER, PHOTOSENSITIVE RESIN COMPOSITION, CURED PRODUCT, AND DISPLAY

(71) Applicant: CENTRAL GLASS COMPANY, LIMITED, Yamaguchi (JP)

(72) Inventors: Yuki FURUYA, Saitama (JP); Yuta SAKAIDA, Saitama (JP); Keita HATTORI, Saitama (JP); Yuzuru KANEKO, Saitama (JP)

(73) Assignee: CENTRAL GLASS COMPANY, LIMITED, Yamaguchi (JP)

(21) Appl. No.: 18/276,528

(22) PCT Filed: Feb. 16, 2022
(86) PCT No.: PCT/JP2022/006086

§ 371 Date: Aug. 9, 2023

(30) Foreign Application Priority Data
Feb. 17, 2021 (JP) 2021-023616

(51) Int. Cl. G03F 7/033; C08F 20/24; C08F 20/28; C08F 290/12; H10K 59/80

(52) U.S. Cl. CPC G03F 7/033; C08F 20/24; C08F 20/28; C08F 290/126; H10K 59/80

(57) ABSTRACT

The present disclosure aims to provide a novel surface modifier that can be introduced into a photosensitive resin composition to improve the surface roughness of a fluororesin suitable for use as a partition wall material. The present disclosure relates to a surface modifier containing a fluororesin (A) having a structure represented by the following formula (1):

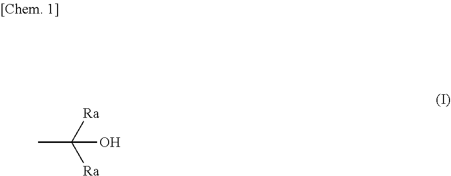

wherein each Ra independently represents a C1-C6 linear, C3-C6 branched, or C3-C6 cyclic alkyl group or a fluorine atom, and any number of hydrogen atoms in the alkyl group are replaced with fluorine atoms.

### TECHNICAL FIELD

The present disclosure relates to a surface modifier, a photosensitive resin composition, a cured product, and a display.

### BACKGROUND ART

The inkjet method is known as a technique for forming an organic layer having a light emitting function or the like in the production of a display element such as an organic EL display, a micro-LED display, or a quantum dot display. There are several inkjet methods. Specific methods include one in which ink is dropped from a nozzle into the recesses of a patterned film having recesses and projections formed on a substrate and the ink is then solidified; and one in which a patterned film is formed on a substrate in advance to provide a lyophilic portion that gets wet with ink and a liquid-repellant portion that repels ink, and ink droplets are dropped onto the patterned film, whereby the ink is attached only to the lyophilic portion.

Particularly, in the former method, in which ink dropped from a nozzle into the recesses of a patterned film is solidified, mainly two processes are applicable to produce such a patterned film having recesses and projections. One is a photolithography process in which the surface of a photosensitive resist film applied to a substrate is exposed to light in a pattern form to form exposed and unexposed portions, and either of the portions is dissolved in a developer and removed; and the other is an imprinting process that uses printing technology.

The projections of the patterned film having recesses and projections formed are called banks (partition walls). The banks serve as barriers against mixing of ink droplets when ink is dropped into the recesses of the patterned film. To enhance the effect of the barriers, the substrate surface is required to be exposed at the recesses of the patterned film and to be lyophilic to ink, and the upper bank surface is required to have liquid repellency with respect to ink.

Such banks may be formed with fluororesins as ink-repellent agents. The use of fluororesins improves the liquid repellency.

Patent Literature 1 discloses a fluororesin-containing resist composition which contains a fluororesin (A) that contains a monomer unit derived from a monomer represented by the formula below and has a fluorine atom content of 7 to 35 mass %, and a photosensitive component reactive with light having a wavelength of 100 to 600 nm, wherein the percentage of the fluororesin (A) relative to the total solids of the resist composition is 0.1 to 30 mass %, and the photosensitive component contains a photoacid generator (B), an alkali-soluble resin (C) containing a carboxy group and/or a phenolic hydroxy group, and an acid crosslinking agent (D) which is a compound having two or more groups that are reactive with a carboxy group or a phenolic hydroxy group by the action of acid.

CH₂═C(R)COOXR^{f1}

In the formula, R represents a hydrogen atom, a methyl group, or a trifluoromethyl group, X represents a C1-C6 divalent organic group containing no fluorine atom, and R^{f1} represents a C4-C6 perfluoroalkyl group.

Patent Literature 2 discloses an ink-repellent agent containing a fluorine atom-containing polymerization unit, wherein the ink-repellent agent includes a polymer containing a polymerization unit (b1) having an alkyl group of C20 or less in which at least one hydrogen atom is replaced with a fluorine atom, provided that the alkyl group includes one having an ether-oxygen atom, and a polymerization unit (b2) having an ethylenic double bond, and the ink-repellent agent has a fluorine content of 5 to 25 mass % and a number average molecular weight of at least 500 but less than 10,000.

Patent Literature 3 discloses a fluororesin-containing resist composition which contains a fluororesin (A) that contains a monomer unit derived from a monomer represented by the formula below, has an ethylenic double bond, and has a fluorine atom content of 7 to 35 mass %, and a photosensitive component reactive with light having a wavelength of 100 to 600 nm, wherein the percentage of the fluororesin (A) relative to the total solids of the resist composition is 0.1 to 30 mass %, and the photosensitive component contains a photo-radical initiator (E) and an alkali-soluble resin (F) that has in one molecule an acidic group and two or more ethylenic double bonds.

CH₂═C(R)COOXR^{f1}

In the formula, R and R^{f1} are as defined above.

Patent Literature 4 discloses a negative photosensitive resin composition containing a fluorine atom-containing ink-repellent agent, wherein the negative photosensitive resin composition contains a photocurable alkali-soluble resin or alkali-soluble monomer (A), a photo-radical polymerization initiator (B), a photoacid generator (C), an acid curing agent (D), and a fluorine atom-containing ink-repellent agent (E), and the ink-repellent agent (E) has a fluorine atom content of 1 to 40 mass % and contains an ethylenic double bond.

### CITATION LIST

### Patent Literature

Patent Literature 1: JP 4474991 B
Patent Literature 2: JP 4488098 B
Patent Literature 3: JP 4905563 B
Patent Literature 4: JP 6536578 B

### SUMMARY OF INVENTION

### Technical Problem

While the fluororesins and ink-repellent agents disclosed in Patent Literatures 1 to 4 are resins with excellent liquid repellency and are suitable as partition wall materials, it has been found that these resins still have room for improvement in surface roughness after curing.

Thus, the present disclosure addresses the issue of improving the surface roughness of fluororesins suitable for use as partition wall materials.

### Solution to Problem

In view of the problems above, the present inventors made extensive studies. As a result, they have found that the use of a fluororesin having a specific group as a surface modifier can solve the above issue, thereby arriving at the present disclosure.

Specifically, the present disclosure is as follows.

A surface modifier of the present disclosure contains a fluororesin (A) having a structure represented by the following formula (1):

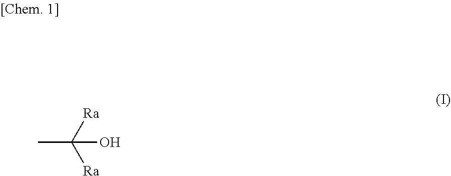

wherein each Ra independently represents a C1-C6 linear, C3-C6 branched, or C3-C6 cyclic alkyl group or a fluorine atom, and any number of hydrogen atoms in the alkyl group are replaced with fluorine atoms.

Introducing and using the surface modifier of the present disclosure in a photosensitive resin composition enables the production of partition walls with improved surface roughness.

A photosensitive resin composition of the present disclosure contains the surface modifier; a fluororesin (B) having a crosslinking site; a solvent; and a photopolymerization initiator.

Use of the photosensitive resin composition of the present disclosure enables the production of partition walls with improved surface roughness.

A cured product of the present disclosure is obtained by curing the photosensitive resin composition.

The use of the photosensitive resin composition of the present disclosure enables the production of a cured product and partition walls with improved surface roughness.

A display of the present disclosure includes a luminescent element including: a partition wall obtained by curing the photosensitive resin composition; and a luminescent layer or a wavelength conversion layer placed in a region partitioned by the partition wall.

The display of the present disclosure includes a partition wall obtained from the photosensitive resin composition, and thus provides a display including a luminescent element in which ink is patterned with high precision.

A method of modifying a surface of a molded article of the present disclosure includes a fluororesin (A) having a structure represented by the above formula (1).

Use of the present disclosure is use of a fluororesin (A) having a structure represented by the above formula (1) for modifying a surface of a molded article.

### Advantageous Effects of Invention

The present disclosure can improve the surface roughness of fluororesins suitable for use as partition wall materials.

### DESCRIPTION OF EMBODIMENTS

The present disclosure is described in detail below. The present disclosure is not limited to the embodiments below and may be appropriately implemented based on the conventional knowledge of those skilled in the art without impairing the gist of the present disclosure.

### (Surface Modifier)

### <Fluororesin (A)>

A surface modifier of the present disclosure contains a fluororesin (A) having a structure represented by the following formula (1).

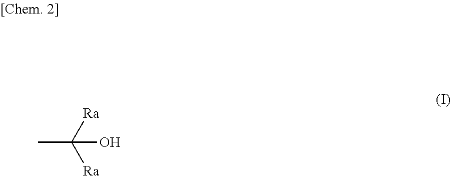

In formula (1), each Ra independently represents a C1-C6 linear, C3-C6 branched, or C3-C6 cyclic alkyl group or a fluorine atom, and any number of hydrogen atoms in the alkyl group are replaced with fluorine atoms.

Examples of the C1-C6 linear alkyl group include a trifluoromethyl group, a difluoromethyl group, a pentafluoroethyl group, a 2,2,2-trifluoroethyl group, a heptafluoropropyl group, a 3,3,3-trifluoropropyl group, and a nonafluorobutyl group. Examples of the C3-C6 branched alkyl group include a heptafluoroisopropyl group, a hexafluoroisopropyl group, a nonafluoroisobutyl group, and a nonafluoro-tert-butyl group. Examples of the C3-C6 cyclic alkyl group include a pentafluorocyclopropyl group. Ra is preferably a C1-C6 linear alkyl group, more preferably a trifluoromethyl group.

Specific examples of the structure of formula (1) include a difluoromethanol group, a tetrafluoroethanol group, a hexafluoroisopropanol group, and a trifluoropropanol group, with a hexafluoroisopropanol group being preferred.

In the fluororesin (A), the structure of formula (1) is preferably not directly bound to an aromatic ring. The structure of formula (1) is preferably directly bound to a linear, branched, or cyclic alkylene group.

The fluororesin (A) can be produced by polymerizing a monomer having the structure of formula (1).

Examples of the monomer having the structure of formula (1) include 5,5,5-trifluoro-4-hydroxy-4-(trifluoromethyl)pentan-2-yl methacrylate, 4-(1,1,1,3,3,3-hexafluoro-2-hydroxy-2-propanyl)styrene (4-HFA-ST), 3,5-bis(1,1,1,3,3,3-hexafluoro-2-hydroxy-2-propanyl)styrene (3,5-HFA-ST), 2,4-bis(1,1,1,3,3,3-hexafluoro-2-hydroxy-2-propanyl)cyclohexyl methacrylate, 3,5-bis(1,1,1,3,3,3-hexafluoro-2-hydroxy-2-propanyl)cyclohexyl methacrylate, 2,4,6-tris(1,1,1,3,3,3-hexafluoro-2-hydroxy-2-propanyl)cyclohexyl methacrylate, and 1,3-bis(1,1,1,3,3,3-hexafluoro-2-hydroxy-2-propanyl)isopropyl methacrylate. One or two or more such monomers may be used. Preferred are 5,5,5-trifluoro-4-hydroxy-4-(trifluoromethyl)pentan-2-yl methacrylate, 3,5-bis(1,1,1,3,3,3-hexafluoro-2-hydroxy-2-propanyl)cyclohexyl methacrylate, and 1,3-bis(1,1,1,3,3,3-hexafluoro-2-hydroxy-2-propanyl)isopropyl methacrylate.

In one embodiment, the fluororesin (A) is preferably a homopolymer produced by polymerizing only any one of these monomers, or a heteropolymer produced by copolymerizing only any two or more of these monomers. This is because such polymers are easy to polymerize and have excellent properties as surface modifiers.

The fluororesin (A) may contain a constitutional unit derived from an additional monomer other than the monomer having the structure of formula (1). Examples of such additional monomers include monomers used for the synthesis of the fluororesin (B) having a crosslinking site described later. One or two or more additional monomers may be used. Specific examples of additional monomers include hexafluoroisopropyl methacrylate and butyl methacrylate.

When the fluororesin (A) contains the constitutional unit derived from an additional monomer, the amount thereof in the fluororesin (A) is preferably 50 mol % or less. When the amount of the constitutional unit derived from an additional monomer is more than 50 mol %, the fluororesin (A) may have an insufficient surface-modifying effect. The amount is more preferably 30 mol % or less.

The molar ratio of the constitutional units derived from monomers in the fluororesin (A) can be determined from the measurements of nuclear magnetic resonance spectroscopy (NMR).

In the present disclosure, the fluororesin (A) functions as a surface modifier, and thus preferably has no crosslinking site.

The amount of the structure of formula (1) in the fluororesin (A) is preferably at least 50 mol % but not more than 300 mol % relative to 100 mol % of the total amount of the repeating units constituting the fluororesin (A). When the amount of the structure of formula (1) is less than 50 mol %, the fluororesin (A) may have an insufficient effect as a surface modifier. When the amount is more than 300 mol %, time-consuming synthesis is required, resulting in increased production costs, which is not preferred. The amount is more preferably at least 100 mol % but not more than 200 mol %.

The fluororesin (A) preferably has a weight average molecular weight of at least 1,000 but not more than 50,000. When the fluororesin (A) has a weight average molecular weight outside the above range, the surface roughness of the resin film or partition walls may not be sufficiently improved. The weight average molecular weight is more preferably at least 5,000 but not more than 40,000, still more preferably at least 5,000 but not more than 30,000.

The fluororesin (A) preferably has a dispersity (Mw/Mn: the ratio of the weight average molecular weight Mw to the number average molecular weight Mn) of 1.01 to 5.00, more preferably 1.10 to 4.00, particularly preferably 1.30 to 3.00.

In the present disclosure, the weight average molecular weight and dispersity of the fluororesin (A) are determined by high performance gel permeation chromatography using polystyrene standards.

The fluororesin (A) may be synthesized, for example, by dissolving monomer(s) in a solvent, adding a polymerization initiator, and reacting them, optionally with heating. The reaction is preferably performed in the presence of a chain transfer agent if necessary. The entire amounts of the monomer(s), solvent, polymerization initiator, and chain transfer agent may be added at the start of the reaction, or they may be added continuously.

The solvent used in the synthesis method is not limited. Examples include ketones, alcohols, polyhydric alcohols and their derivatives, ethers, esters, aromatic solvents, and fluorine solvents. These may be used alone or in admixtures of two or more.

Specific examples of the ketones include acetone, methyl ethyl ketone (MEK), cyclopentanone, cyclohexanone, methyl isoamyl ketone, 2-heptylcyclopentanone, methyl isobutyl ketone, methyl isopentyl ketone, and 2-heptanone.

Specific examples of the alcohols include isopropanol, butanol, isobutanol, n-pentanol, isopentanol, tert-pentanol, 4-methyl-2-pentanol, 3-methyl-3-pentanol, 2,3-dimethyl-2-pentanol, n-hexanol, n-heptanol, 2-heptanol, n-octanol, n-decanol, s-amyl alcohol, t-amyl alcohol, isoamyl alcohol, 2-ethyl-1-butanol, lauryl alcohol, hexyl decanol, and oleyl alcohol.

Specific examples of the polyhydric alcohols and their derivatives include ethylene glycol, ethylene glycol monoacetate, ethylene glycol dimethyl ether, diethylene glycol, diethylene glycol dimethyl ether, diethylene glycol monoacetate, propylene glycol, propylene glycol monoacetate, propylene glycol monomethyl ether (PGME), propylene glycol monoethyl ether, propylene glycol monopropyl ether, propylene glycol monobutyl ether, propylene glycol monomethyl ether acetate (PGMEA), and monomethyl ether, monoethyl ether, monopropyl ether, monobutyl ether, and monophenyl ether of dipropylene glycol or dipropylene glycol monoacetate.

Specific examples of the ethers include diethyl ether, diisopropyl ether, tetrahydrofuran, dioxane, and anisole.

Specific examples of the esters include methyl lactate, ethyl lactate (EL), methyl acetate, ethyl acetate, butyl acetate, methyl pyruvate, ethyl pyruvate, methyl methoxypropionate, ethyl ethoxypropionate, and γ-butyrolactone.

Examples of the aromatic solvents include xylene and toluene.

Examples of the fluorine solvents include chlorofluorocarbons, hydrochlorofluorocarbons, hydrofluorocarbons, perfluoro compounds, and hexafluoroisopropyl alcohol.

Examples of the polymerization initiator include known organic peroxides, inorganic peroxides, and azo compounds. Organic peroxides or inorganic peroxides may be combined with reducing agents and used as redox catalysts.

Examples of the chain transfer agent include: mercaptans such as n-butylmercaptan, n-dodecylmercaptan, t-butylmercaptan, ethyl thioglycolate, 2-ethylhexyl thioglycolate, and 2-mercaptoethanol; and alkyl halides such as chloroform, carbon tetrachloride, and carbon tetrabromide.

The amount of the fluororesin (A) in the surface modifier of the present disclosure is not limited, but is, for example, preferably 0.001 to 99.99 mass %, more preferably 0.01 to 99.9 mass %. The surface modifier of the present disclosure may contain one fluororesin (A) alone or a mixture of two or more fluororesins (A). The surface modifier of the present disclosure may contain a solvent or additives in addition to the fluororesin (A). Examples of solvents that may be contained in the surface modifier of the present disclosure include PGMEA and butyl acetate.

Since the surface modifier of the present disclosure contains the fluororesin (A) having a structure of formula (1), it can be suitably used as a surface modifier for various resins. For example, introducing and using the surface modifier of the present disclosure in a resin composition enables the production of a molded article such as a resin film or partition walls (banks) with improved surface roughness. Any type of resin may be used in the resin composition, such as one or a combination of two or more of the following resins: olefin resins, epoxy resins, (meth)acrylic resins, urethane resins, fluororesins, etc. The surface modifier of the present disclosure can be particularly suitably used in a composition containing two or more resins differing in the amount of fluorine.

More specifically, the surface modifier of the present disclosure can be used as a defoaming agent, a leveling agent, an anti-popping agent, etc. The surface modifier of the present disclosure can also be used as a surfactant because it also acts as a surfactant.

### (Photosensitive Resin Composition)

The photosensitive resin composition of the present disclosure contains the surface modifier described above, a fluororesin (B) having a crosslinking site, a solvent, and a photopolymerization initiator. Use of the photosensitive resin composition containing the surface modifier enables the production of a resin film or partition walls with improved surface roughness.

Herein, the term “bank” or “banks” is a synonym to the term “partition wall” or “partition walls”, and these terms refer to the projection(s) of a patterned film having recesses and projections used in an inkjet method, unless otherwise specified.

Examples of the surface modifier in the photosensitive resin composition of the present disclosure include those containing the above-described fluororesin (A).

In the photosensitive resin composition of the present disclosure, the amount of the fluororesin (A) is preferably at least 0.01 mass % but not more than 4.0 mass % relative to the total solids of the photosensitive resin composition. When the amount is outside the above range, the surface roughness of the resin film or partition walls may not be sufficiently improved. The amount is more preferably at least 0.1 mass % but not more than 2.5 mass %, still more preferably at least 0.2 mass % but not more than 2.5 mass %.

### <Fluororesin (B) Having Crosslinking Site>

In the photosensitive resin composition of the present disclosure, the fluororesin (B) having a crosslinking site has a repeating unit derived from a hydrocarbon containing a fluorine atom and contains a photopolymerizable group as a crosslinking site in the side chain of the polymer. Herein, the crosslinking site of the “fluororesin (B) having a crosslinking site” means a site polymerizable with another monomer.

Hereinafter, the term “fluororesin (B) having a crosslinking site” may also be referred to as “fluororesin (B)”.

In the photosensitive resin composition of the present disclosure, the fluororesin (B) may have a structure represented by the following chemical formula (2) or may have a structure represented by the following formula (3).

[Chem. 3]

—CR²═CRb₂ (2)

In formula (2), each Rb independently represents a C1-C6 linear, C3-C6 branched, or C3-C6 cyclic alkyl group or a fluorine atom, and any number of hydrogen atoms in the alkyl group are replaced with fluorine atoms; and R² represents a hydrogen atom or a C1-C6 linear, C3-C6 branched, or C3-C6 cyclic alkyl group.

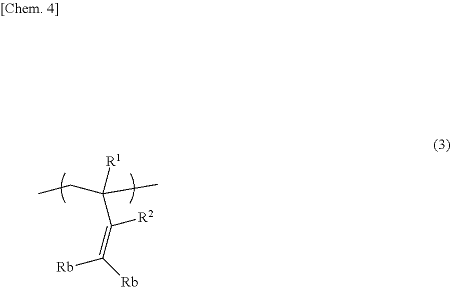

In formula (3), each Rb independently represents a C1-C6 linear, C3-C6 branched, or C3-C6 cyclic alkyl group or a fluorine atom, and any number of hydrogen atoms in the alkyl group are replaced with fluorine atoms; R¹ represents a hydrogen atom, a fluorine atom, or a methyl group; and R² represents a hydrogen atom or a C1-C6 linear, C3-C6 branched, or C3-C6 cyclic alkyl group.

In formula (3), R¹ is preferably a hydrogen atom or a methyl group, and examples of R² include a hydrogen atom, a methyl group, an ethyl group, an n-propyl group, an isopropyl group, an n-butyl group, a 1-methylpropyl group, a 2-methylpropyl group, a tert-butyl group, an n-pentyl group, an isopentyl group, a 1,1-dimethylpropyl group, a 1-methylbutyl group, a 1,1-dimethylbutyl group, an n-hexyl group, a cyclopentyl group, and a cyclohexyl group, with a hydrogen atom, a methyl group, an ethyl group, an n-propyl group, and an isopropyl group being preferred, with a hydrogen atom or a methyl group being more preferred.

Moreover, Rb in formula (2) or (3) is preferably a fluorine atom, a trifluoromethyl group, a difluoromethyl group, a pentafluoroethyl group, a 2,2,2-trifluoroethyl group, an n-heptafluoropropyl group, a 2,2,3,3,3-pentafluoropropyl group, a 3,3,3-trifluoropropyl group, a hexafluoroisopropyl group, a heptafluoroisopropyl group, an n-nonafluorobutyl group, an isononafluorobutyl group, or a tert-nonafluorobutyl group; more preferably a fluorine atom, a trifluoromethyl group, a difluoromethyl group, a pentafluoroethyl group, a 2,2,2-trifluoroethyl group, an n-heptafluoropropyl group, a 2,2,3,3,3-pentafluoropropyl group, a 3,3,3-trifluoropropyl group, or a hexafluoroisopropyl group; particularly preferably a fluorine atom, a difluoromethyl group, or a trifluoromethyl group.

The following structures are preferred examples of the repeating unit represented by formula (3) in the fluororesin (B) in the photosensitive resin composition of the present disclosure.

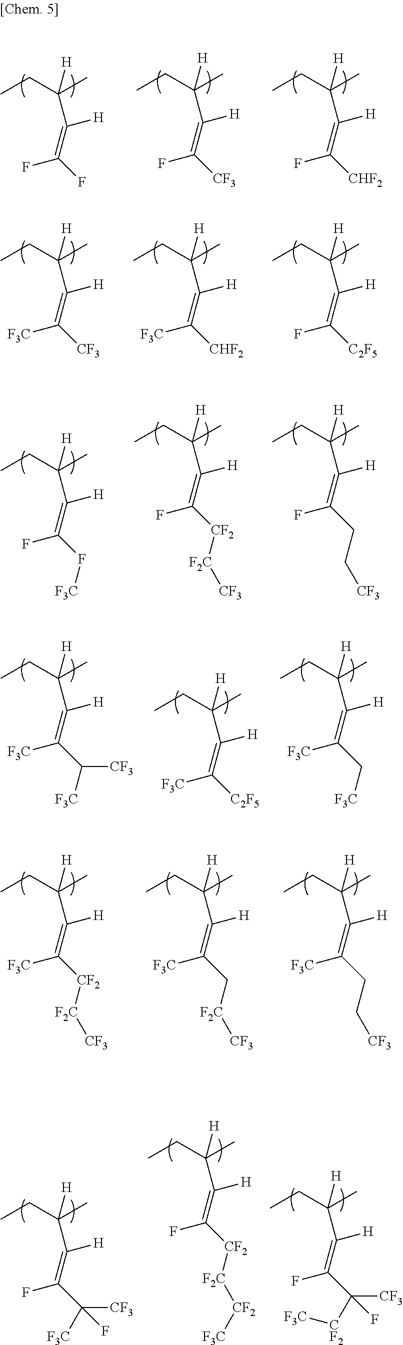

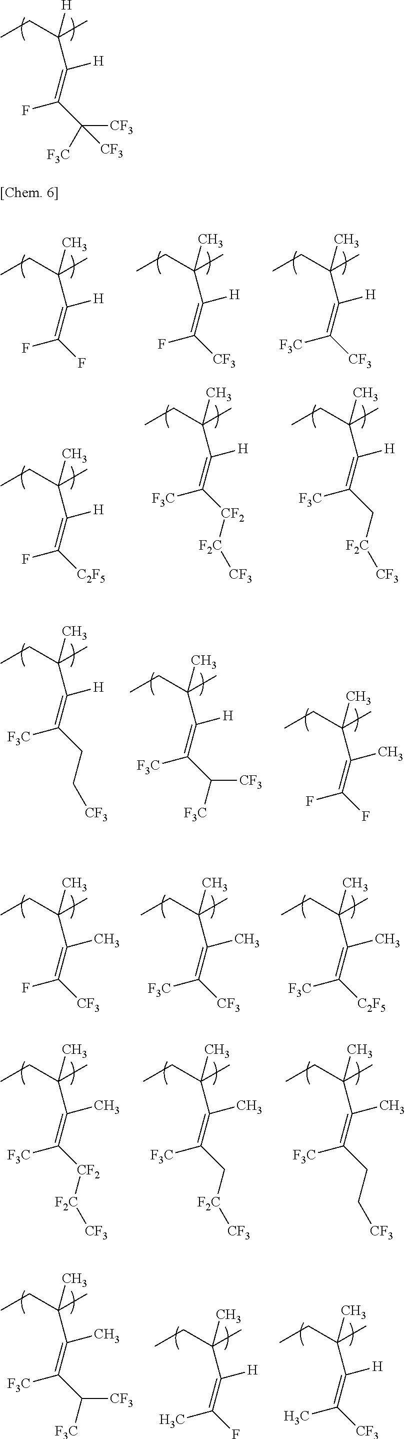

The amount of the repeating unit of formula (3) in the fluororesin (B) is preferably at least 5 mol % but not more than 70 mol %, more preferably at least 10 mol % but not more than 50 mol %, particularly preferably at least 10 mol % but not more than 30 mol %, relative to 100 mol % of the total repeating units constituting the fluororesin (B).

When the amount of the repeating unit of formula (3) is more than 70 mol %, the fluororesin (B) tends to be less soluble in solvents, while when the amount of the repeating unit of formula (3) is less than 5 mol %, the resistance to UV-ozone treatment or oxygen plasma treatment tends to decrease.

The fluororesin (B) having the repeating unit of formula (3) is one preferred embodiment because it has resistance to UV-ozone treatment or oxygen plasma treatment.

Also, in the photosensitive resin composition of the present disclosure, the fluororesin (B) may include a structure represented by the following formula (4).

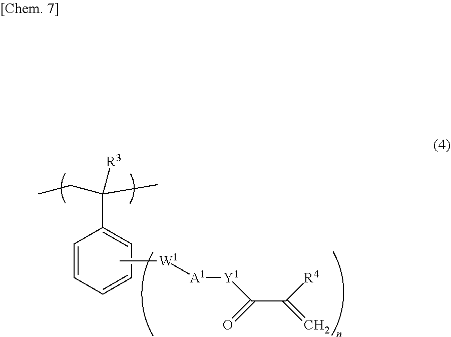

In formula (4), R³ and R⁴ each independently represent a hydrogen atom or a methyl group.

In formula (4), W¹ represents a divalent linking group and represents —O—, —O—C(═O)—, —C(═O)—O—, —O—C(═O)—NH—, —C(═O)—O—C(═O)—NH—, or —C(═O)—NH—. Preferred of these is —O—C(═O)—NH—, —C(═O)—O—C(═O)—NH—, or —C(═O)—NH—.

The fluororesin (B) in which W¹ is —O—C(═O)—NH— is one preferred embodiment because it has better ink repellency after UV-ozone treatment or oxygen plasma treatment.

In formula (4), A¹ represents a divalent linking group and represents a C1-C10 linear, C3-C10 branched, or C3-C10 cyclic alkylene group in which any number of hydrogen atoms may be replaced with hydroxy groups or —O—C(═O)—CH₃.

When the divalent linking group A¹ is a C1-C10 linear alkylene group, examples thereof include a methylene group, an ethylene group, a propylene group, an n-butylene group, an n-pentylene group, an n-hexalene group, an n-heptalene group, an n-octalene group, an n-nonalene group, and an n-decalene group.

When the divalent linking group A¹ is a C3-C10 branched alkylene group, examples thereof include an isopropylene group, an isobutylene group, a sec-butylene group, a tert-butylene group, an isopentalene group, and an isohexalene group.

When the divalent linking group A¹ is a C3-C10 cyclic alkylene group, examples thereof include disubstituted cyclopropanes, disubstituted cyclobutanes, disubstituted cyclopentanes, disubstituted cyclohexanes, disubstituted cycloheptanes, disubstituted cyclooctanes, disubstituted cyclodecanes, and disubstituted 4-tert-butylcyclohexanes.

When any number of hydrogen atoms in these alkylene groups are replaced with hydroxy groups, examples of such hydroxy group-substituted alkylene groups include a hydroxyethylene group, a 1-hydroxy-n-propylene group, a 2-hydroxy-n-propylene group, a hydroxy-isopropylene group (—CH(CH₂OH)CH₂—), a 1-hydroxy-n-butylene group, a 2-hydroxy-n-butylene group, a hydroxy-sec-butylene group (—CH(CH₂OH)CH₂CH₂—), a hydroxy-isobutylene group (—CH₂CH(CH₂OH)CH₂—), and a hydroxy-tert-butylene group (—C(CH₂OH) (CH₃)CH₂—).

Also, when any number of hydrogen atoms in these alkylene groups are replaced with —O—C(═O)—CH₃, examples of such substituted alkylene groups include those in which the hydroxy groups of the hydroxy group-substituted alkylene groups exemplified above are replaced with —O—C(═O)—CH₃.

Of these, the divalent linking group A¹ is preferably a methylene group, an ethylene group, a propylene group, an n-butylene group, an isobutylene group, a sec-butylene group, a cyclohexyl group, a 2-hydroxy-n-propylene group, a hydroxy-isopropylene group (—CH(CH₂OH)CH₂—), a 2-hydroxy-n-butylene group, or a hydroxy-sec-butylene group (—CH(CH₂OH)CH₂CH₂—); more preferably an ethylene group, a propylene group, a 2-hydroxy-n-propylene group, or a hydroxy-isopropylene group (—CH(CH₂OH)CH₂—); particularly preferably an ethylene group or a 2-hydroxy-n-propylene group.

In formula (4), Y¹ represents a divalent linking group and represents —O— or —NH—, with —O— being more preferred.

In formula (4), n represents an integer of 1 to 3, with n of 1 being particularly preferred.

The substituents are each independently in the ortho, meta, or para position of the aromatic ring, with the para position being preferred.

The following structures are preferred examples of the repeating unit represented by formula (4). In the examples, the substituent position on the aromatic ring is the para position, but the substituents may be each independently in the ortho or meta position.

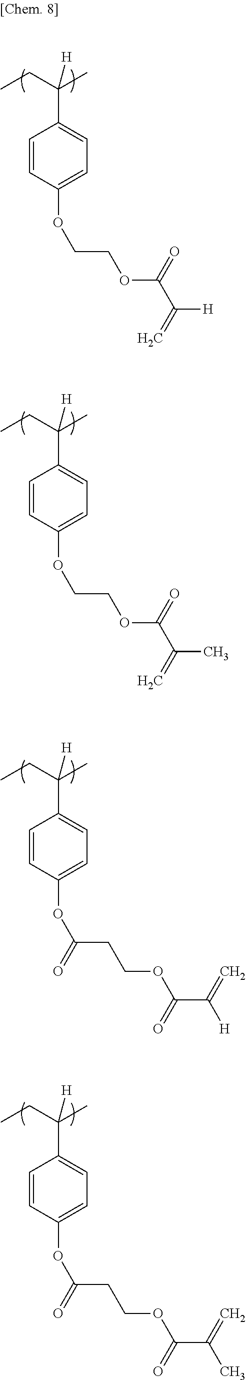

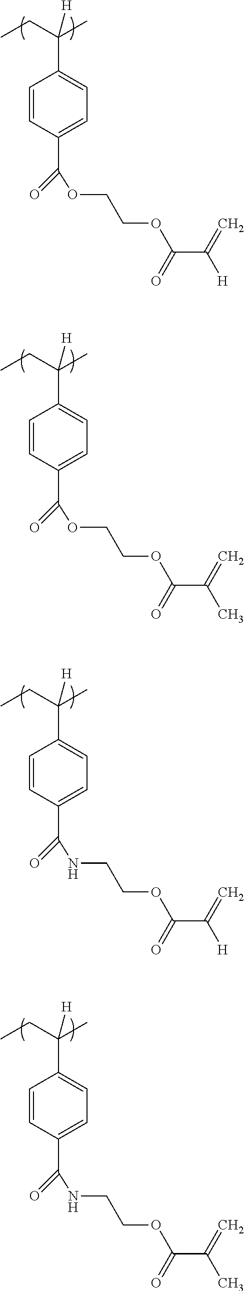

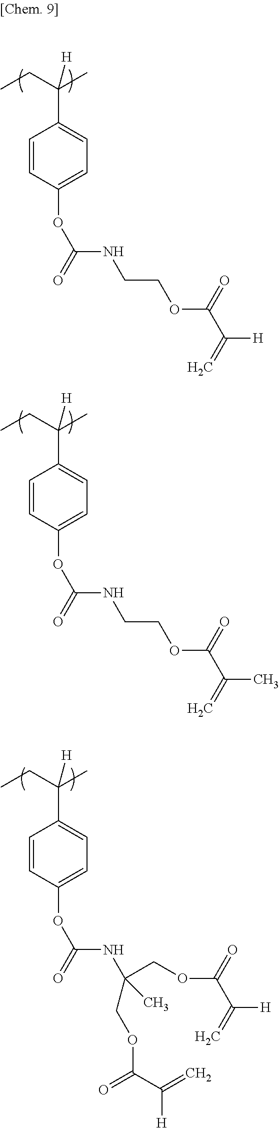

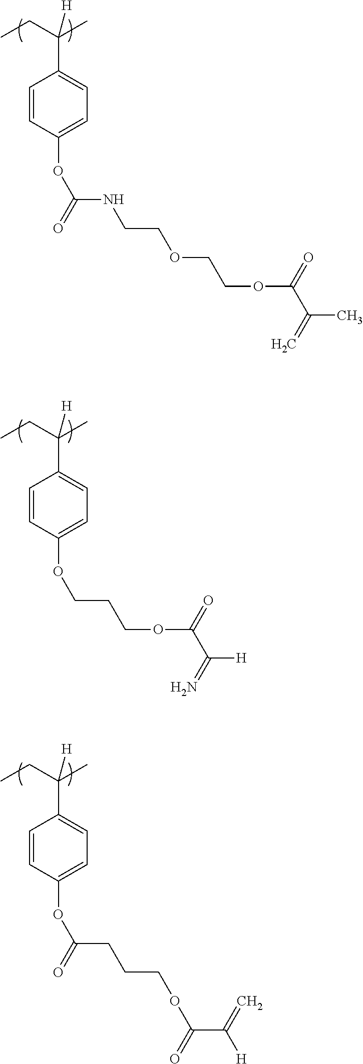

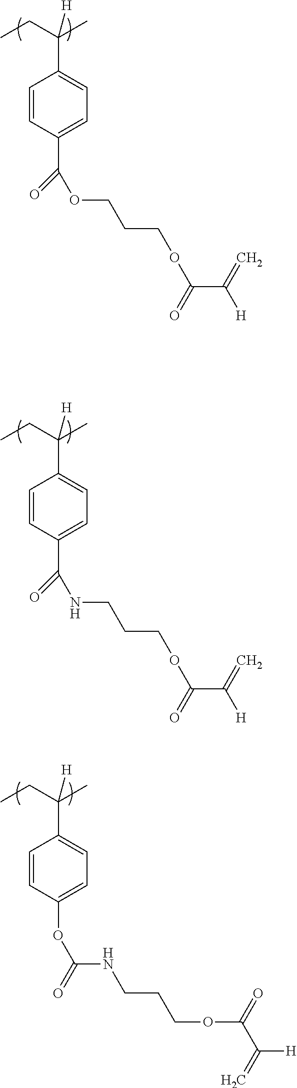

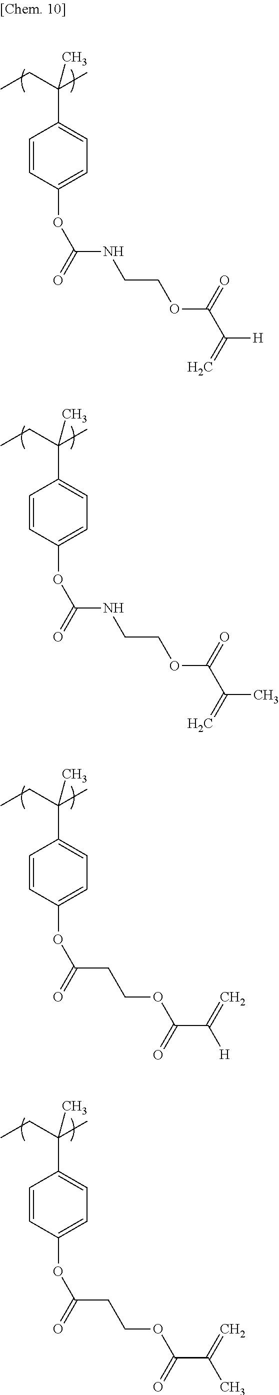

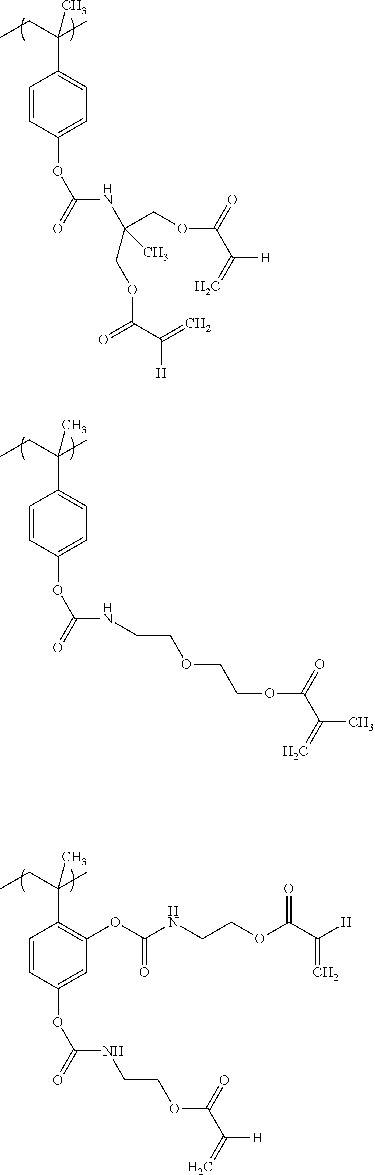

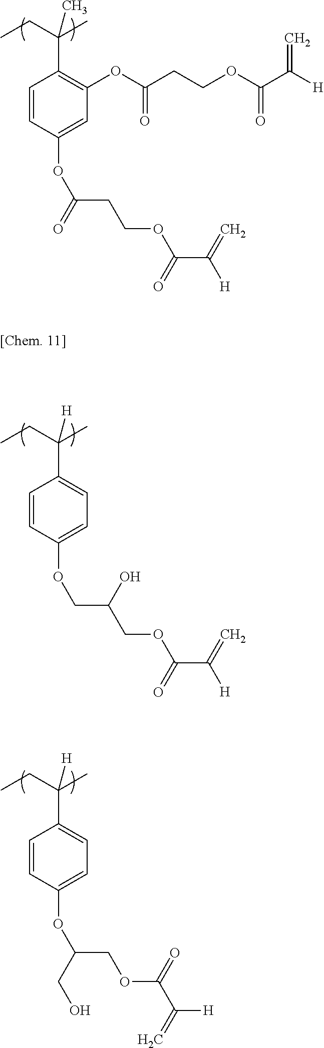

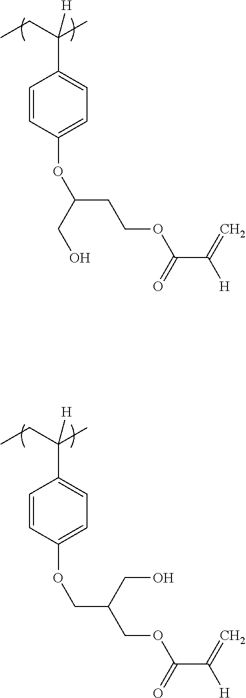

The amount of the repeating unit of formula (4) in the fluororesin (B) is preferably at least 5 mol % but not more than 70 mol %, more preferably at least 10 mol % but not more than 50 mol %, particularly preferably at least 10 mol % but not more than 30 mol %, relative to 100 mol % of the total repeating units constituting the fluororesin (B).

When the amount of the repeating unit of formula (4) is more than 70 mol %, the fluororesin (B) tends to be less soluble in solvents, while when the amount of the repeating unit of formula (4) is less than 5 mol %, the resistance to UV-ozone treatment or oxygen plasma treatment tends to decrease.

Here, the effect of the repeating unit of formula (4) of the present disclosure is not clear, but it is believed that the repeating unit has resistance to UV-ozone treatment or oxygen plasma treatment. However, the effect of the present disclosure is not limited to the effect described here.

As described above, the fluororesin (B) of the present disclosure may be a mixture (blend) of a copolymer containing a repeating unit of formula (3) and a repeating unit of formula (4) and another copolymer containing a repeating unit of formula (3) and a repeating unit of formula (4). Particularly, in one preferred embodiment of the present disclosure, the fluororesin (B) of the present disclosure is a mixture of a fluororesin containing a repeating unit of formula (4) wherein W² is —O—C(═O)—NH— and a fluororesin containing a repeating unit of formula (4) wherein W² is —C(═O)—NH—.

Moreover, in the photosensitive resin composition of the present disclosure, the fluororesin (B) may include a structure represented by the following formula (5).

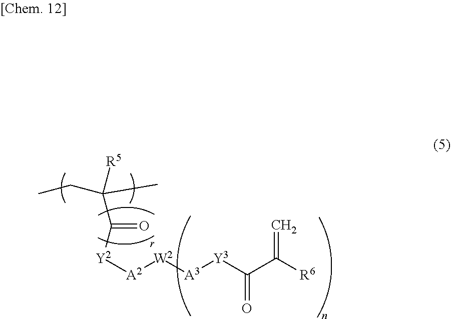

In formula (5), R⁵ and R⁶ each independently represent a hydrogen atom or a methyl group.

In formula (5), W² represents a divalent linking group and represents —O—, —O—C(═O)—, —C(═O)—O—, —O—C(═O)—NH—, —C(═O)—O—C(═O)—NH—, or —C(═O)—NH—. Preferred of these is —O—C(═O)—NH—, —C(═O)—O—C(═O)—NH—, or —C(═O)—NH—.

The fluororesin (B) of the present disclosure in which W² is —O—C(═O)—NH— is one particularly preferred embodiment because it has better ink repellency after UV-ozone treatment or oxygen plasma treatment.

In formula (5), A² and A³ each independently represent a divalent linking group and represent a C1-C10 linear, C3-C10 branched, or C3-C10 cyclic alkylene group in which any number of hydrogen atoms may be replaced with hydroxy groups or —O—C(═O)—CH₃.

When the divalent linking groups A² and A³ are each independently a C1-C10 linear alkylene group, examples thereof include a methylene group, an ethylene group, a propylene group, an n-butylene group, an n-pentylene group, an n-hexalene group, an n-heptalene group, an n-octalene group, an n-nonalene group, and an n-decalene group.

When the divalent linking groups A² and A³ are each independently a C3-C10 branched alkylene group, examples thereof include an isopropylene group, an isobutylene group, a sec-butylene group, a tert-butylene group, an isopentalene group, and an isohexalene group.

When the divalent linking groups A² and A³ are each independently a C3-C10 cyclic alkylene group, examples thereof include disubstituted cyclopropanes, disubstituted cyclobutanes, disubstituted cyclopentanes, disubstituted cyclohexanes, disubstituted cycloheptanes, disubstituted cyclooctanes, disubstituted cyclodecanes, and disubstituted 4-tert-butylcyclohexanes.

When any number of hydrogen atoms in these alkylene groups are replaced with hydroxy groups, examples of such hydroxy group-substituted alkylene groups include a 1-hydroxyethylene group (—CH(OH)CH₂—), a 2-hydroxyethylene group (—CH₂CH(OH)—), a 1-hydroxy-n-propylene group, a 2-hydroxy-n-propylene group, a hydroxy-isopropylene group (—CH(CH₂OH)CH₂—), a 1-hydroxy-n-butylene group, a 2-hydroxy-n-butylene group, a hydroxy-sec-butylene group (—CH(CH₂OH)CH₂CH₂—), a hydroxy-isobutylene group (—CH₂CH(CH₂OH)CH₂—), and a hydroxy-tert-butylene group (—C(CH₂OH) (CH₃)CH₂—).

Also, when any number of hydrogen atoms in these alkylene groups are replaced with —O—C(═O)—CH₃, examples of such substituted alkylene groups include those in which the hydroxy groups of the hydroxy group-substituted alkylene groups exemplified above are replaced with —O—C(═O)—CH₃.

Of these, the divalent linking groups A² and A³ are each independently preferably a methylene group, an ethylene group, a propylene group, an n-butylene group, an isobutylene group, a sec-butylene group, a cyclohexyl group, a 1-hydroxyethylene group (—CH(OH)CH₂—), a 2-hydroxyethylene group (—CH₂CH(OH)—), a 2-hydroxy-n-propylene group, a hydroxy-isopropylene group (—CH(CH₂OH)CH₂—), a 2-hydroxy-n-butylene group, or a hydroxy-sec-butylene group (—CH(CH₂OH)CH₂CH₂—); more preferably an ethylene group, a propylene group, a 1-hydroxyethylene group (—CH(OH)CH₂—), a 2-hydroxyethylene group (—CH₂CH(OH)—), a 2-hydroxy-n-propylene group, or a hydroxy-isopropylene group (—CH(CH₂OH)CH₂—); particularly preferably an ethylene group, a 1-hydroxyethylene group (—CH(OH)CH₂—), or a 2-hydroxyethylene group (—CH₂CH(OH)—).

In formula (5), Y² and Y³ represent divalent linking groups and each independently represent —O— or —NH—, with —O— being more preferred.

In formula (5), n represents an integer of 1 to 3, with n of 1 being particularly preferred.

In formula (5), r represents 0 or 1. When r is 0, (—C(═O)—) represents a single bond.

The following structures are preferred examples of the repeating unit represented by formula (5).

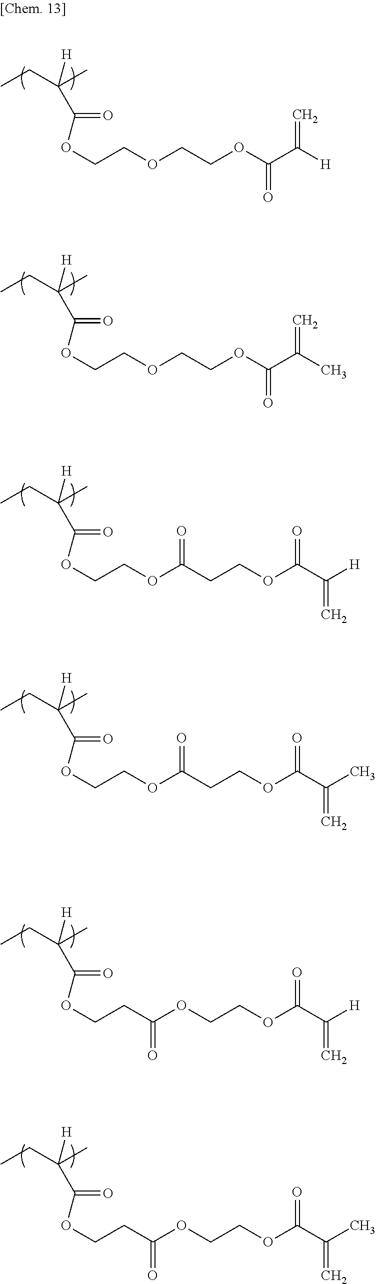

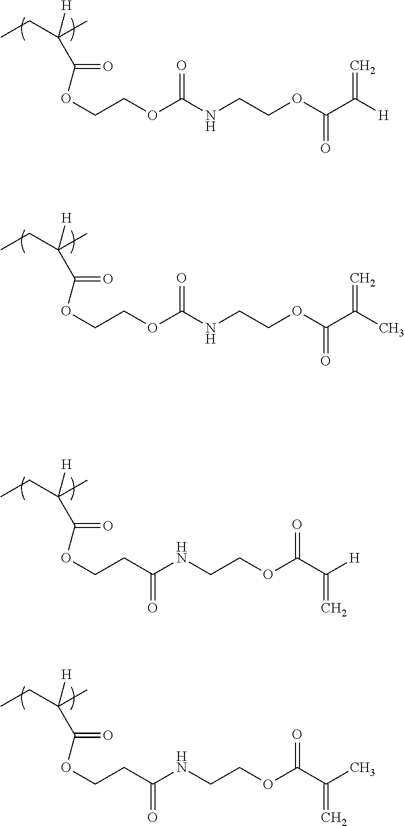

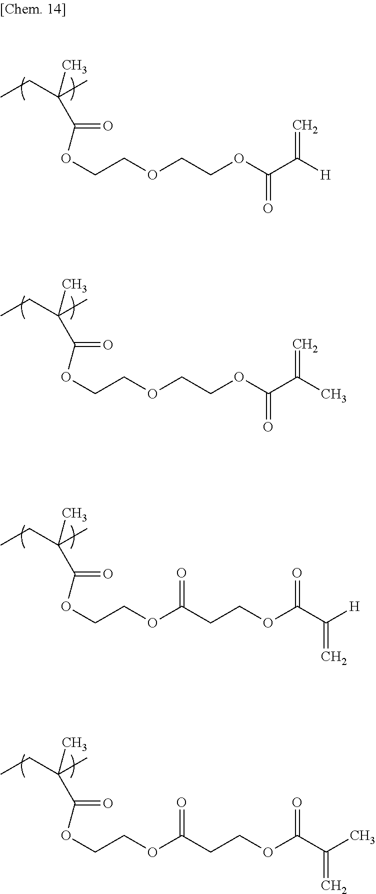

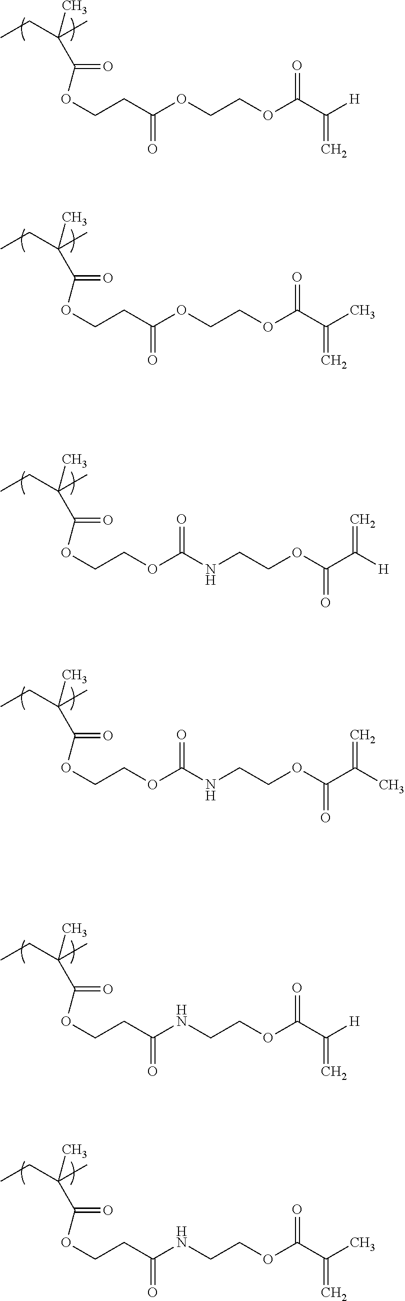

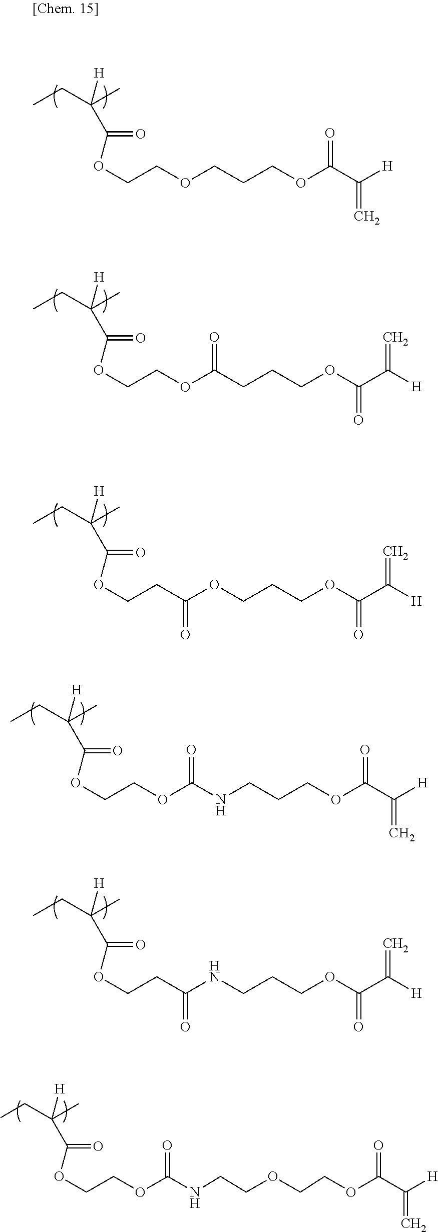

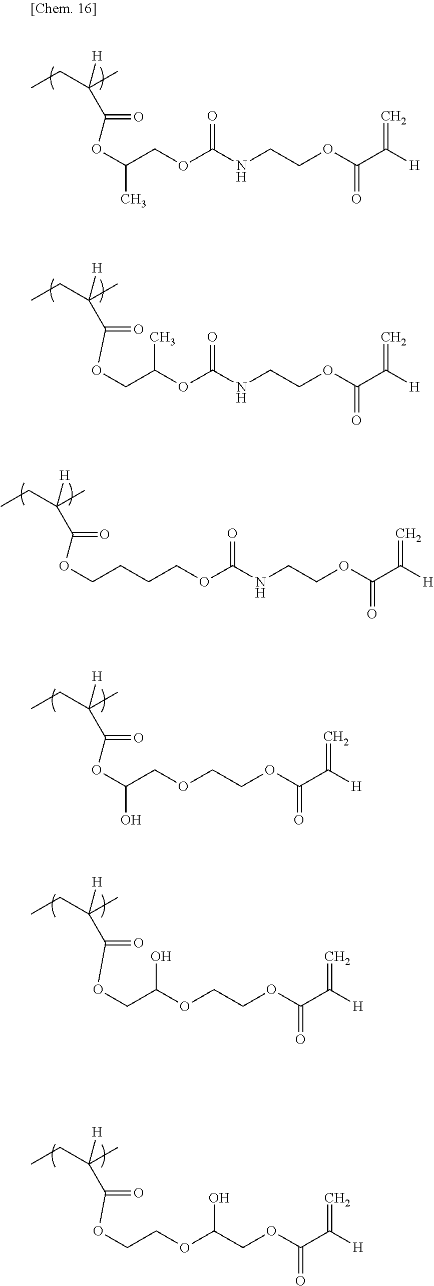

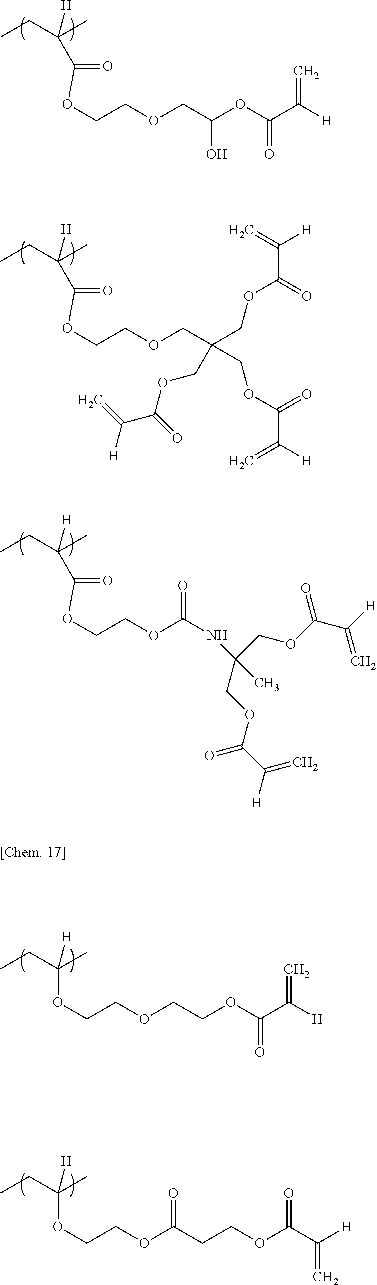

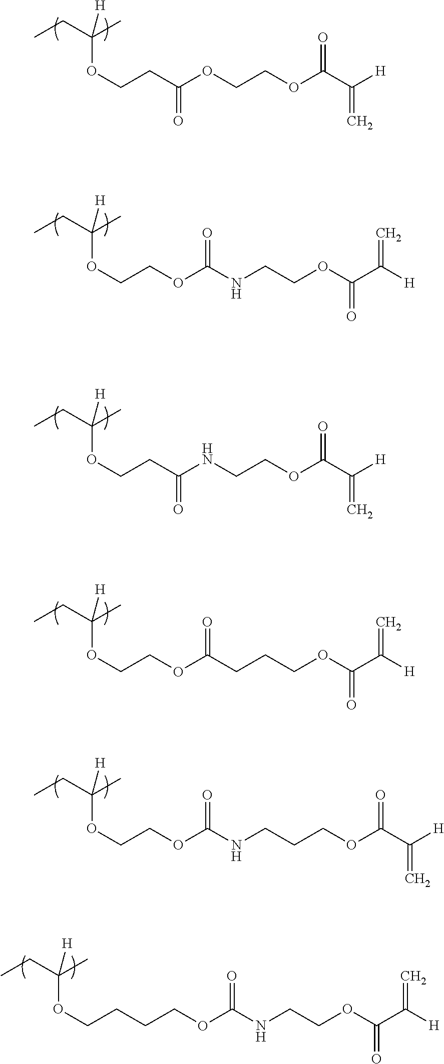

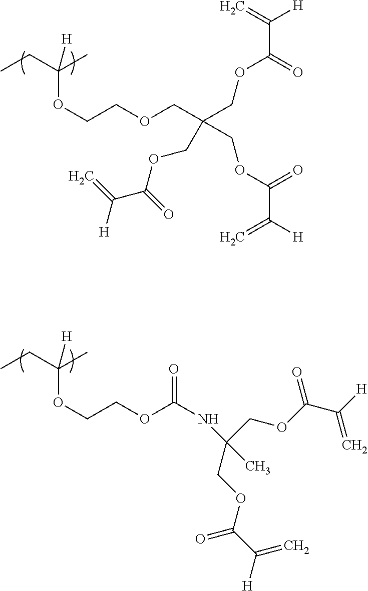

The amount of the repeating unit of formula (5) in the fluororesin (B) is preferably at least 5 mol % but not more than 70 mol %, more preferably at least 10 mol % but not more than 50 mol %, particularly preferably at least 10 mol % but not more than 30 mol %, relative to 100 mol % of the total repeating units constituting the fluororesin (B).

When the amount of the repeating unit of formula (5) is more than 70 mol %, the fluororesin (B) tends to be less soluble in solvents, while when the amount of the repeating unit of formula (5) is less than 5 mol %, the resin film or banks produced from the fluororesin (B) tend to have lower adhesion to substrates.

The effect of the repeating unit of formula (5) is not clear, but it is believed that the presence of the repeating unit of formula (5) in the fluororesin (B) improves the adhesion of the resulting resin film or banks to substrates. However, the effect of the present disclosure is not limited to the effect described here.

The fluororesin (B) may be a mixture (blend) of a copolymer containing a repeating unit of formula (3) and a repeating unit of formula (5) and another copolymer containing a repeating unit of formula (3) and a repeating unit of formula (5). Particularly, in one preferred embodiment of the present disclosure, the fluororesin of the present disclosure is a mixture of a fluororesin containing a repeating unit of formula (5) wherein W² is —O—C(═O)—NH— and a fluororesin containing a repeating unit of formula (5) wherein W² is —C(═O)—NH—.

Moreover, in the photosensitive resin composition of the present disclosure, the fluororesin (B) may include a structure represented by the following formula (6).

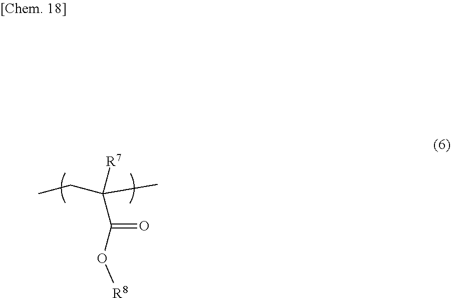

In formula (6), R⁷ represents a hydrogen atom or a methyl group.

In formula (6), R⁸ represents a C1-C15 linear, C3-C15 branched, or C3-C15 cyclic alkyl group in which any number of hydrogen atoms are replaced with fluorine atoms, and the repeating unit has a fluorine content of 30 mass % or more.

When R⁸ is a linear alkyl group, specific examples thereof include a methyl group, an ethyl group, a propyl group, a butyl group, a pentyl group, a hexyl group, a heptyl group, an octyl group, a nonyl group, and C10-C14 linear alkyl groups in which any number of hydrogen atoms are replaced with fluorine atoms.

When R⁸ is a linear alkyl group, the repeating unit represented by formula (6) is preferably a repeating unit represented by the following formula (6-1).

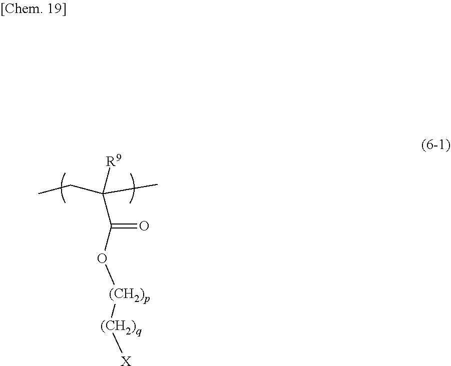

In formula (6-1), R⁹ is the same as R⁷ in formula (6).

In formula (6-1), X is a hydrogen atom or a fluorine atom.

In formula (6-1), p is an integer of 1 to 4 and q is an integer of 1 to 14. Particularly preferably, p is an integer of 1 or 2, q is an integer of 2 to 8, and X is a fluorine atom.

The following structures are preferred examples of the repeating unit of formula (6).

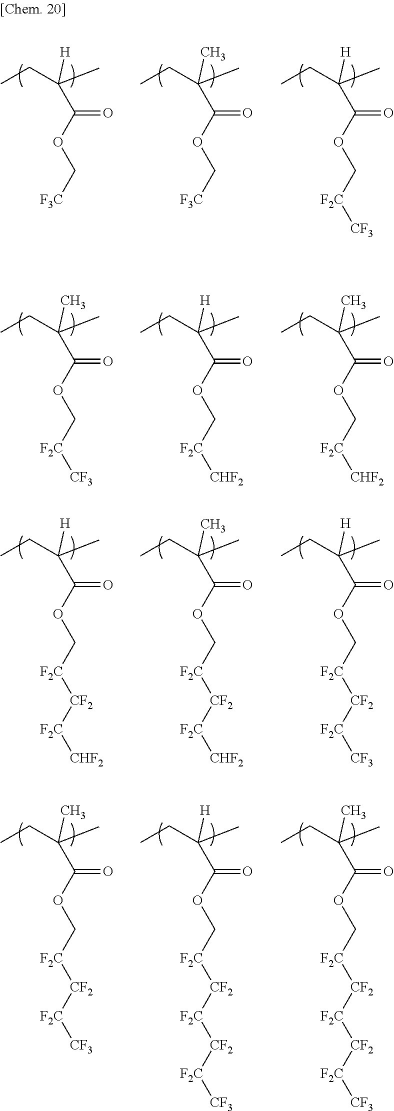

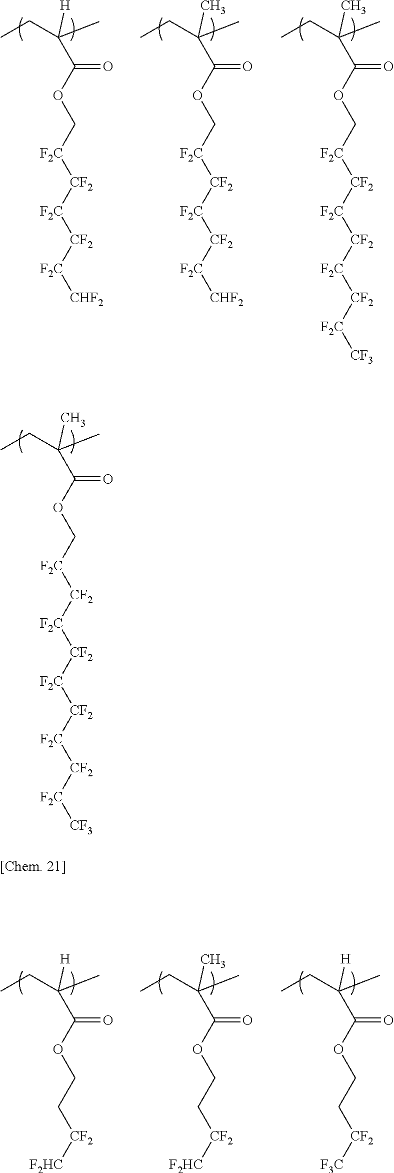

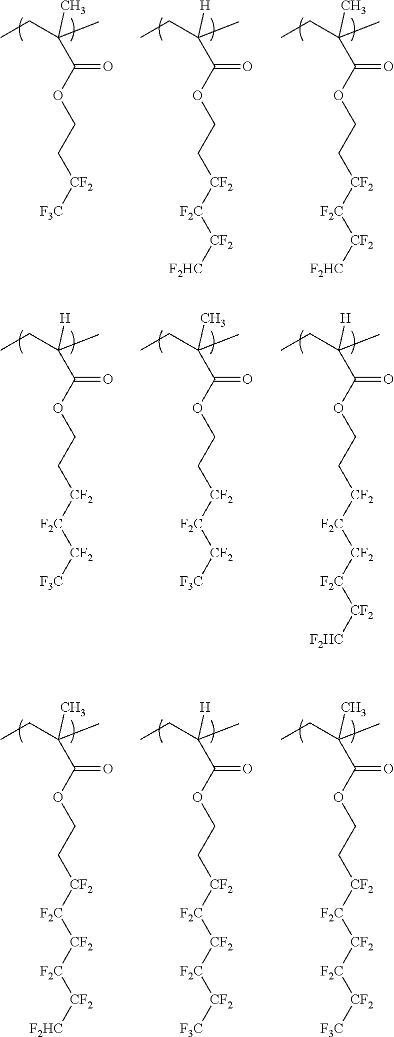

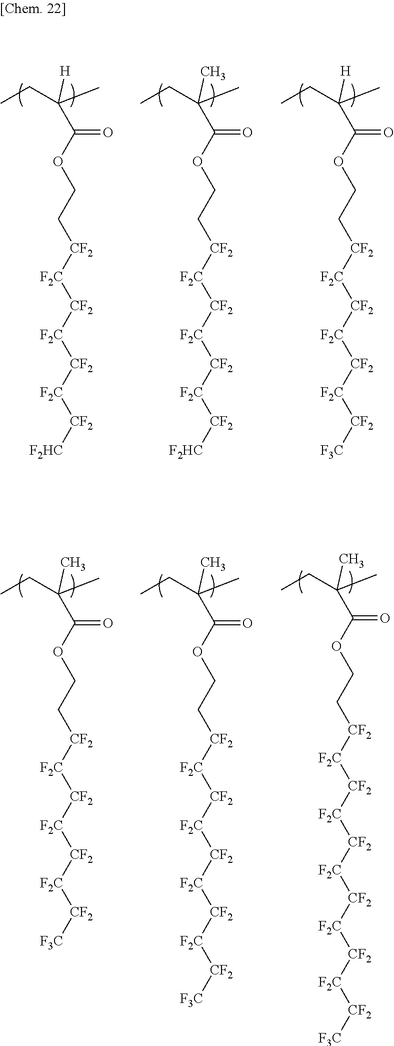

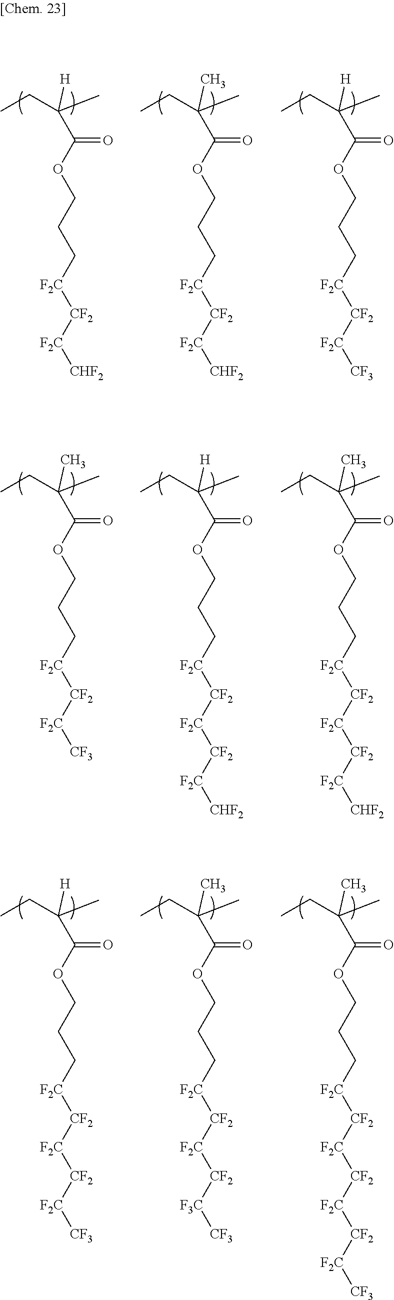

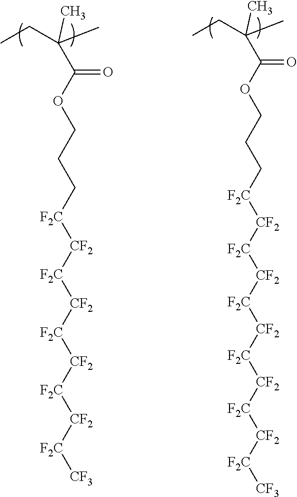

The amount of the repeating unit of formula (6) is preferably at least 5 mol % but not more than 70 mol %, more preferably at least 10 mol % but not more than 50 mol %, particularly preferably at least 10 mol % but not more than 30 mol %, relative to 100 mol % of the total repeating units constituting the fluororesin (B).

When the amount of the repeating unit of formula (6) is more than 70 mol %, the fluororesin (B) tends to be less soluble in solvents.

The repeating unit of formula (6) is a repeating unit that imparts ink repellency after UV-ozone treatment or oxygen plasma treatment. Thus, when it is desired to pursue high ink repellency, the fluororesin (B) of the present disclosure preferably contains the repeating unit of formula (6).

Moreover, in the photosensitive resin composition of the present disclosure, the fluororesin (B) may include a structure represented by the following formula (7).

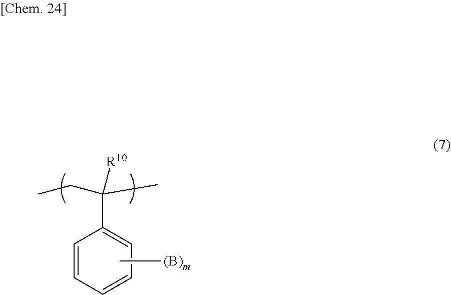

In formula (7), R¹⁰ represents a hydrogen atom or a methyl group.

In formula (7), each B independently represents a hydroxy group, a carboxy group, —C(═O)—O—R¹¹ (where R¹¹ represents a C1-C15 linear, C3-C15 branched, or C3-C15 cyclic alkyl group in which any number of hydrogen atoms are replaced with fluorine atoms, and R¹¹ has a fluorine content of 30 mass % or more), or —O—C(═O)—R¹² (where R¹² represents a C1-C6 linear, C3-C6 branched, or C3-C6 cyclic alkyl group); and m represents an integer of 0 to 3.

The following structures are preferred examples of the repeating unit represented by formula (7).

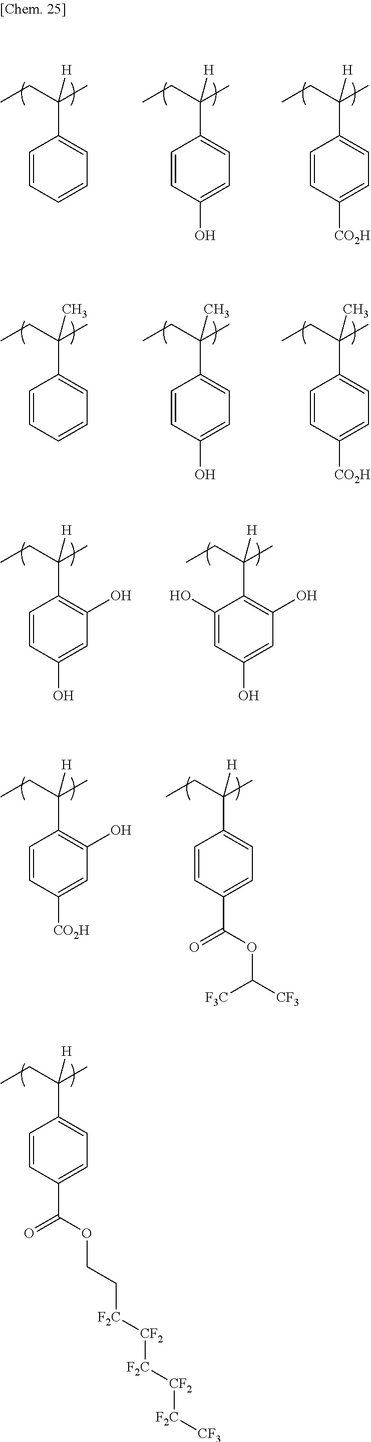

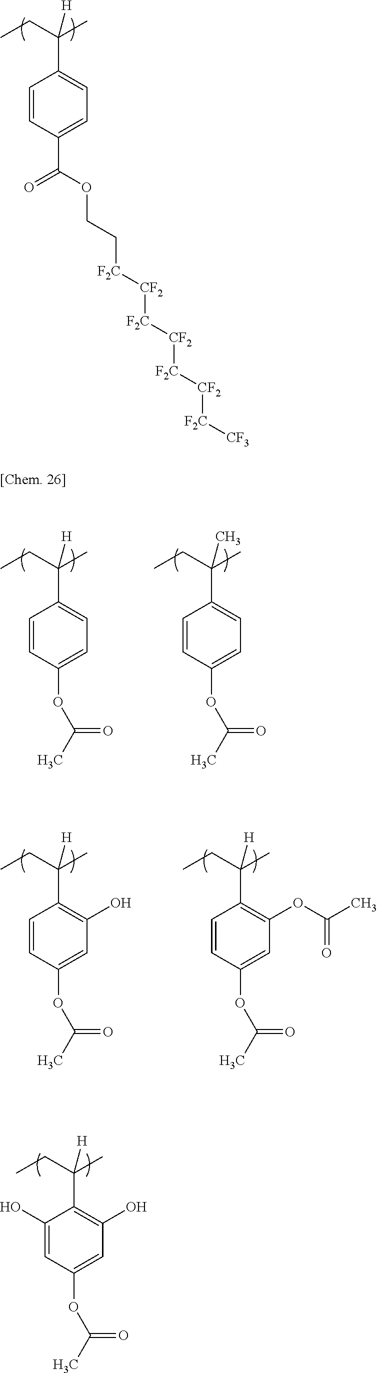

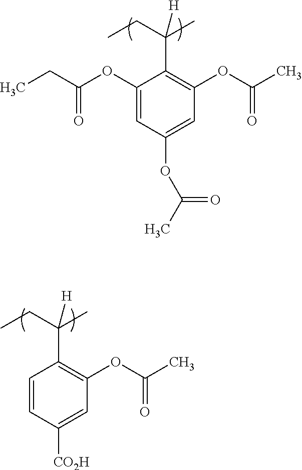

The amount of the repeating unit of formula (7) is preferably at least 5 mol % but not more than 70 mol %, more preferably at least 10 mol % but not more than 50 mol %, particularly preferably at least 20 mol % but not more than 40 mol %, relative to 100 mol % of the total repeating units constituting the fluororesin (B).

When the amount of the repeating unit of formula (7) is more than 70 mol %, the fluororesin (B) tends to be less soluble in solvents.

The repeating unit of formula (7) wherein B is a hydroxy group or a carboxy group has solubility in an alkali developer. Thus, when it is desired to impart alkali developability to the fluororesin film produced from the fluororesin (B), the fluororesin (B) of the present disclosure preferably contains the repeating unit of formula (7) wherein B is a hydroxy group or a carboxy group.

Moreover, in the photosensitive resin composition of the present disclosure, the fluororesin (B) may include a structure represented by the following formula (8).

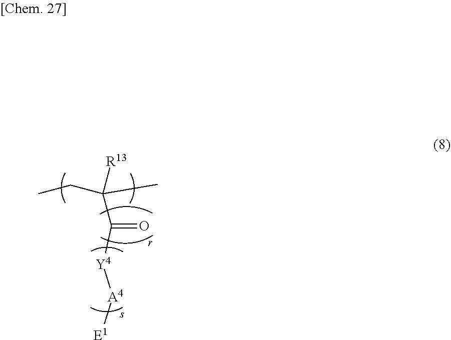

In formula (8), R¹³ represents a hydrogen atom or a methyl group.

In formula (8), A⁴ represents a divalent linking group and represents a C1-C10 linear, C3-C10 branched, or C3-C10 cyclic alkylene group in which any number of hydrogen atoms may be replaced with hydroxy groups or —O—C(═O)—CH₃.

When the divalent linking group A⁴ is a C1-C10 linear alkylene group, examples thereof include a methylene group, an ethylene group, a propylene group, an n-butylene group, an n-pentylene group, an n-hexalene group, an n-heptalene group, an n-octalene group, an n-nonalene group, and an n-decalene group.

When the divalent linking group A⁴ is a C3-C10 branched alkylene group, examples thereof include an isopropylene group, an isobutylene group, a sec-butylene group, a tert-butylene group, an isopentalene group, and an isohexalene group.

When the divalent linking group A⁴ is a C3-C10 cyclic alkylene group, examples thereof include disubstituted cyclopropanes, disubstituted cyclobutanes, disubstituted cyclopentanes, disubstituted cyclohexanes, disubstituted cycloheptanes, disubstituted cyclooctanes, disubstituted cyclodecanes, and disubstituted 4-tert-butylcyclohexanes.

When any number of hydrogen atoms in these alkylene groups are replaced with hydroxy groups, examples of such hydroxy group-substituted alkylene groups include a 1-hydroxyethylene group (—CH(OH)CH₂—), a 2-hydroxyethylene group (—CH₂CH(OH)—), a 1-hydroxy-n-propylene group, a 2-hydroxy-n-propylene group, a hydroxy-isopropylene group (—CH(CH₂OH)CH₂—), a 1-hydroxy-n-butylene group, a 2-hydroxy-n-butylene group, a hydroxy-sec-butylene group (—CH(CH₂OH)CH₂CH₂—), a hydroxy-isobutylene group (—CH₂CH(CH₂OH)CH₂—), and a hydroxy-tert-butylene group (—C(CH₂OH) (CH₃)CH₂—).

Also, when any number of hydrogen atoms in these alkylene groups are replaced with —O—C(═O)—CH₃, examples of such substituted alkylene groups include those in which the hydroxy groups of the hydroxy group-substituted alkylene groups exemplified above are replaced with —O—C(═O)—CH₃.

Of these, the divalent linking group A⁴ is preferably a methylene group, an ethylene group, a propylene group, an n-butylene group, an isobutylene group, a sec-butylene group, a cyclohexyl group, a 1-hydroxyethylene group (—CH(OH)CH₂—), a 2-hydroxyethylene group (—CH₂CH(OH)—), a 2—CH(CH₂OH)CH₂—), a 2-hydroxy-n-butylene group, or a hydroxy-sec-butylene group (—CH(CH₂OH)CH₂CH₂—); more preferably an ethylene group, a propylene group, a 1-hydroxyethylene group (—CH(OH)CH₂—), a 2-hydroxyethylene group (—CH₂CH(OH)—), a 2-hydroxy-n-propylene group, or a hydroxy-isopropylene group (—CH(CH₂OH)CH₂—); particularly preferably an ethylene group, a 1-hydroxyethylene group (—CH(OH)CH₂—), or a 2-hydroxyethylene group (—CH₂CH(OH)—).

In formula (8), Y⁴ represents a divalent linking group and represents —O— or —NH—, with —O— being more preferred.

In formula (8), r represents 0 or 1. When r is 0, (—C(═O)—) represents a single bond.

In formula (8), E¹ represents a hydroxy group, a carboxy group, or an oxirane group.

When E¹ is an oxirane group, examples thereof include an ethylene oxide group, a 1,2-propylene oxide group, and a 1,3-propylene oxide group. Preferred of these is an ethylene oxide group.

In formula (8), s represents 0 or 1. When s is 0, (-Y⁴-A⁴-) represents a single bond. When r is 0 and s is 0, the repeating unit forms a structure in which E¹ is bonded to the main chain.

The following structures are preferred examples of the repeating unit represented by formula (8).

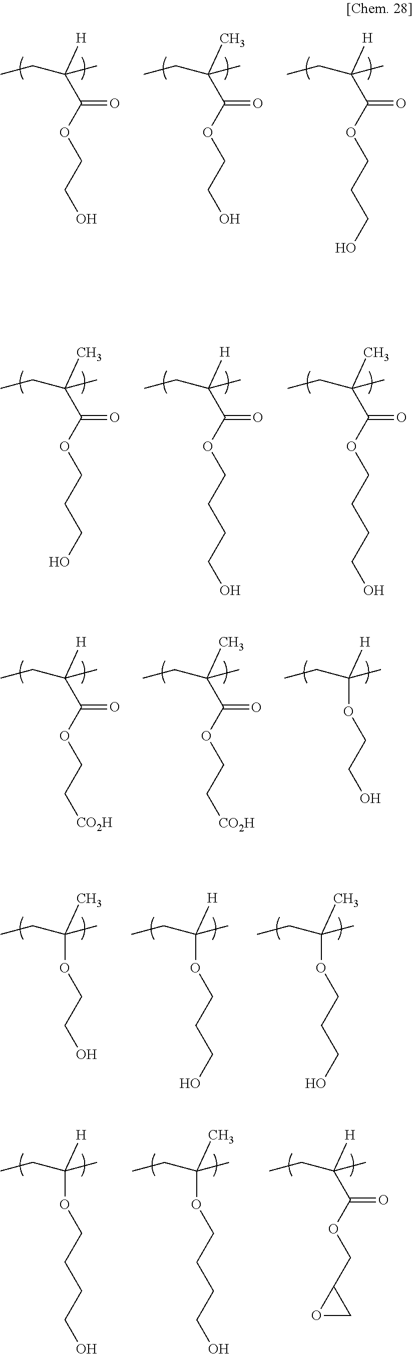

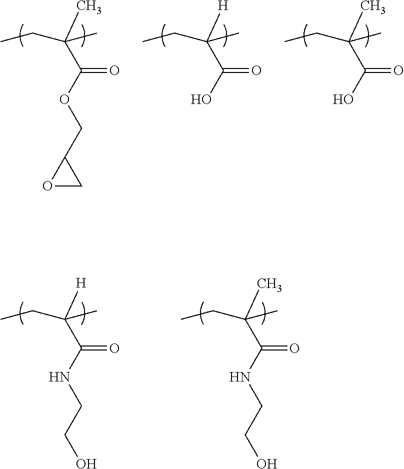

When E¹ in formula (8) is a hydroxy group or a carboxy group, the repeating unit of formula (8) imparts solubility in an alkali developer to the fluororesin (B). Thus, when it is desired to impart alkali developability to the film produced from the fluororesin (B), the fluororesin (B) of the present disclosure preferably contains the repeating unit of formula (8) wherein E¹ is a hydroxy group or a carboxy group.

For example, the fluororesin (B) having a crosslinking site can be produced by polymerizing monomers to obtain a fluororesin precursor containing a repeating unit of any of the structures of formulas (3) and (6) to (8) described above, and then reacting the fluororesin precursor with a photopolymerizable group derivative to introduce a photopolymerizable group into the side chain of the polymer, whereby a fluororesin (B) containing a repeating unit of the structure of formula (4) or (5) described above can be synthesized.

The photopolymerizable group to be introduced into the fluororesin precursor is preferably an acrylic group, a methacrylic group, a vinyl group, or an allyl group, more preferably an acrylic group.

When an acrylic group is introduced as the photopolymerizable group, examples of the photopolymerizable group derivative include acrylic acid derivatives such as acrylic group-containing isocyanate monomers and acrylic group-containing epoxy monomers.

Examples of the acrylic group-containing isocyanate monomers include 2-isocyanatoethyl methacrylate, 2-isocyanatoethyl acrylate, 2-(2-methacryloyloxyethyloxy)ethyl isocyanate, and 1,1-(bisacryloyloxymethyl)ethyl isocyanate. Preferred is 2-isocyanatoethyl acrylate.

Examples of the acrylic group-containing epoxy monomers include glycidyl acrylate and 4-hydroxybutyl acrylate glycidyl ether (4HBAGE, available from Mitsubishi Chemical Corporation).

The photopolymerizable group can be introduced into the fluororesin precursor by addition reaction between the hydroxy group of the fluororesin precursor and the photopolymerizable group derivative.

The percentage of the photopolymerizable group in the fluororesin (B) is preferably at least 10 mol % but not more than 70 mol % of the fluororesin (B). When the percentage of the photopolymerizable group is less than 10 mol %, the resin film or partition walls tend to have lower strength. When the percentage of the photopolymerizable group is more than 70 mol %, it may be difficult to form a resin film by application. The percentage is more preferably 15 mol % to 60 mol %.

In the photosensitive resin composition of the present disclosure, the molecular weight of the fluororesin (B), expressed as the mass average molecular weight measured by high performance gel permeation chromatography (GPC) using polystyrene standards, is preferably at least 1,000 but not more than 1,000,000, more preferably at least 2,000 but not more than 500,000, particularly preferably at least 3,000 but not more than 100,000. When the molecular weight is less than 1,000, the formed resin film or banks tend to have lower strength. When the molecular weight is more than 1,000,000, it may be difficult to form a resin film by application due to the lack of solubility in solvents.

The dispersity (Mw/Mn) of the fluororesin (B) is preferably 1.01 to 5.00, more preferably 1.01 to 4.00, particularly preferably 1.01 to 3.00. The fluororesin (B) may be a random copolymer, an alternating copolymer, a block copolymer, or a graft copolymer. Preferably, the fluororesin (B) is a random copolymer in order to disperse the respective characteristics appropriately rather than locally.

The following are preferred embodiments of the fluororesin (B) in the photosensitive resin composition of the present disclosure.

### Embodiment 1

A fluororesin (B) containing a repeating unit represented by the following formula (3), a repeating unit represented by the following formula (5), a repeating unit represented by the following formula (6-1), and a repeating unit represented by the following formula (7).

Formula (3): R¹ and R² are hydrogen atoms, and each Rb is independently a fluorine atom, a difluoromethyl group, or a trifluoromethyl group.
Formula (5): R⁵ and R⁶ are each independently a hydrogen atom or a methyl group; W² is —O—C(═O)—NH—, —C(═O)—O—C(═O)—NH—, or —C(═O)—NH—; A² and A³ are each independently an ethylene group; Y² and Y³ are —O—; n is 1; and r is 1.
Formula (6-1): R⁹ is a methyl group; p is an integer of 2; q is an integer of 4 to 8; and X is a fluorine atom.
Formula (7): R¹⁰ is a hydrogen atom, B is a hydroxy group or a carboxy group, and m is 1.

### Embodiment 2

A fluororesin (B) containing a repeating unit represented by the following formula (5), a repeating unit represented by the following formula (6), a repeating unit represented by the following formula (6-1), and a repeating unit represented by the following formula (8).

Formula (5): R⁵ and R⁶ are each independently a hydrogen atom or a methyl group; W² is —O—C(═O)—NH—, —C(═O)—O—C(═O)—NH—, or —C(═O)—NH—; A² and A³ are each independently an ethylene group; Y² and Y³ are —O—; n is 1; and r is 1. Formula (6): R⁷ is a methyl group and R⁸ is a C3-C15 branched perfluoroalkyl group.
Formula (6-1): R⁹ is a methyl group; p is an integer of 2; q is an integer of 4 to 8; and X is a fluorine atom.
Formula (8): R¹³ is a methyl group; A⁴ is an ethylene group; Y⁴ is —O—; r is 1; s is 0 or 1; and E¹ is a hydroxy group or a carboxy group.

In the photosensitive resin composition of the present disclosure, the fluorine content of the fluororesin (B) is desirably 20 to 50 mass %, more desirably 25 to 40 mass %.

The fluororesin (B) having a fluorine content within this range is easily soluble in solvents. The presence of a fluorine atom in the fluororesin (B) enables the production of a resin film or banks having excellent liquid repellency.

Herein, the “fluorine content of the fluororesin (B)” means the value calculated from the molar percentages of the monomers constituting the fluororesin (B) measured by nuclear magnetic resonance spectroscopy (NMR), the molecular weights of the monomers constituting the fluororesin (B), and the amount of fluorine in each monomer.

The following describes an example of a method of measuring the fluorine content when the fluororesin (B) is a resin produced by polymerizing 1,1-bistri fluoromethylbutadiene, 4-hydroxystyrene, and 2-(perfluorohexyl)ethyl methacrylate.

(i) First, the fluororesin (B) is measured by NMR to calculate the percentage of each constituent (molar percentage).

(ii) The molecular weight (Mw) of each constituent monomer of the fluororesin (B) is multiplied by the molar percentage thereof, and the resulting values are added up to determine the total value. The weight percentage (wt %) of each constituent is calculated from the total value.

Here, the molecular weight of 1,1-bistrifluoromethylbutadiene is 190, the molecular weight of 4-hydroxystyrene is 120, and the molecular weight of 2-(perfluorohexyl)ethyl methacrylate is 432.

(iii) Next, the fluorine content of each constituent monomer containing a fluorine atom is calculated.

(iv) For each component, “[the fluorine content of the monomer]÷[the molecular weight (Mw) of the monomer]×[the weight percentage (wt %) thereof]” is calculated, and the resulting values are added up.

(v) The value obtained in (iv) is divided by the total value obtained in (ii) to calculate the fluorine content of the fluororesin (B).

In the photosensitive resin composition of the present disclosure, one or two or more fluororesins (B) may be used.

The percentage of the fluororesin (B) based on the total solids in the photosensitive resin composition of the present disclosure is preferably 0.1 to 40 mass %, more preferably 1 to 30 mass %. When the percentage is within this range, the resin film has good water repellency, oil repellency, and substrate adhesion.

### <Solvent>

The solvent in the photosensitive resin composition of the present disclosure may be any solvent in which the fluororesin (B) is soluble. Examples include the same solvents as those which can be used in the synthesis of the fluororesin (A). Preferred are methyl ethyl ketone, propylene glycol monomethyl ether acetate (PGMEA), propylene glycol monomethyl ether (PGME), cyclohexanone, ethyl lactate, butyl acetate, and γ-butyrolactone.

The amount of the solvent in the photosensitive resin composition of the present disclosure is preferably in the range of at least 50 parts by mass but not more than 2,000 parts by mass, more preferably at least 100 parts by mass but not more than 1,000 parts by mass, relative to 100 parts by mass of the concentration of the fluororesin (B) (provided that when the photosensitive resin composition contains the alkali-soluble resin (D) described later, the concentration of the fluororesin (B) includes the alkali-soluble resin (D)). Controlling the amount of the solvent can control the thickness of the formed resin film. When the amount is within the above range, the resulting resin film can have a thickness particularly suitable for the production of banks.

### <Photopolymerization Initiator>

In the photosensitive resin composition of the present disclosure, any known photopolymerization initiator can be used as long as it allows a monomer having a polymerizable double bond to be polymerized by high energy rays such as electromagnetic waves or electron beams.

The photopolymerization initiator used may be a photo-radical initiator or a photoacid initiator. These may be used alone, or a photo-radical initiator and a photoacid initiator may be used in combination, or two or more photo-radical initiators or photoacid initiators may be used in admixture. Moreover, the use of the photopolymerization initiator in combination with an additive enables living polymerization in some cases. The additive used may be a known additive.

Specifically, photo-radical initiators can be classified into: the intramolecular cleavage type in which the intramolecular bond can be cleaved by absorption of electromagnetic waves or electron beams to generate radicals; the hydrogen abstraction type that, when used in combination with a hydrogen donor such as a tertiary amine or ether, generates radicals, and other types. Either type can be used. Photo-radical initiators other than those listed above can also be used.

Specific examples of photo-radical initiators include benzophenone-based, acetophenone-based, diketone-based, acylphosphine oxide-based, quinone-based, and acyloin-based photo-radical initiators.

Specific examples of the benzophenone-based photo-radical initiators include benzophenone, 4-hydroxybenzophenone, 2-benzoylbenzoic acid, 4-benzoylbenzoic acid, 4,4′-bis(dimethylamino)benzophenone, and 4,4′-bis(diethylamino)benzophenone. Preferred of these are 2-benzoylbenzoic acid, 4-benzoylbenzoic acid, and 4,4′-bis(diethylamino)benzophenone.

Specific examples of the acetophenone-based photo-radical initiators include acetophenone, 2-(4-toluenesulfonyloxy)-2-phenylacetophenone, p-dimethylaminoacetophenone, 2,2′-dimethoxy-2-phenylacetophenone, p-methoxyacetophenone, 2-methyl-[4-(methylthio)phenyl]-2-morpholino-1-propanone, and 2-benzyl-2-dimethylamino-1-(4-morpholinophenyl)-butan-1-one. Preferred of these is p-dimethylaminoacetophenone or p-methoxyacetophenone.

Specific examples of the diketone-based photo-radical initiators include 4,4′-dimethoxybenzil, methyl benzoylformate, and 9,10-phenanthrenequinone. Preferred of these is 4,4′-dimethoxybenzil or methyl benzoylformate.

Specific examples of the acylphosphine oxide-based photo-radical initiators include bis(2,4,6-trimethylbenzoyl)-phenylphosphine oxide.

Specific examples of the quinone-based photo-radical initiators include anthraquinone, 2-ethylanthraquinone, camphorquinone, and 1,4-naphthoquinone. Preferred of these is camphorquinone or 1,4-naphthoquinone.

Specific examples of the acyloin-based photo-radical initiators include benzoin, benzoin methyl ether, benzoin ethyl ether, and benzoin isopropyl ether. Preferred of these is benzoin or benzoin methyl ether.

Preferred are benzophenone-based, acetophenone-based, and diketone-based photo-radical initiators. More preferred are benzophenone-based photo-radical initiators.

Preferred examples of commercially available photo-radical initiators include Irgacure 127, Irgacure 184, Irgacure 369, Irgacure 651, Irgacure 819, Irgacure 907, Irgacure 2959, Irgacure OXE-01, Darocur 1173, and Lucirin TPO (trade names) available from BASF. More preferred of these is Irgacure 651 or Irgacure 369.

Specifically, a photoacid initiator is an onium salt of a pair of cation and anion in which the cation is at least one selected from the group consisting of an aromatic sulfonic acid, an aromatic iodonium, an aromatic diazonium, an aromatic ammonium, thianthrenium, thioxanthonium, and (2,4-cyclopentadien-1-yl) (1-methylethylbenzene)-iron, and the anion is at least one selected from the group consisting of tetrafluoroborate, hexafluorophosphate, hexafluoroantimonate, and pentafluorophenylborate.

Particularly preferred of these are bis[4-(diphenylsulfonio)phenyl]sulfide bishexafluorophosphate, bis[4-(diphenylsulfonio)phenyl]sulfide tetrakis(pentafluorophenyl)borate, and diphenyliodonium hexafluorophosphate.

Examples of commercially available photoacid generators include CPI-100P, CPI-110P, CPI-101A, CPI-200K, and CPI-210S (trade names) available from San-Apro Ltd.; CYRACURE Photoinitiator UVI-6990, CYRACURE Photoinitiator UVI-6992, and CYRACURE Photoinitiator UVI-6976 (trade names) available from Dow Chemical Japan Limited; ADEKA OPTOMER SP-150, ADEKA OPTOMER SP-152, ADEKA OPTOMER SP-170, ADEKA OPTOMER SP-172, and ADEKA OPTOMER SP-300 (trade names) available from ADEKA CORPORATION; CI-5102 and CI-2855 (trade names) available from Nippon Soda Co., Ltd.; SAN AID SI-60L, SAN AID SI-80L, SAN AID SI-100L, SAN AID SI-110L, SAN AID SI-180L, SAN AID SI-110, and SAN AID SI-180 (trade names) available from Sanshin Chemical Industry Co. Ltd.; Esacure 1064 and Esacure 1187 (trade names) available from Lamberti; and Irgacure 250 (trade name) available from Ciba Specialty Chemicals.

The amount of the photopolymerization initiator in the photosensitive resin composition of the present disclosure is preferably at least 0.1 parts by mass but not more than 30 parts by mass, more preferably at least 1 part by mass but not more than 20 parts by mass, relative to 100 parts by mass of the fluororesin (B) (provided that when the photosensitive resin composition contains the alkali-soluble resin (D) described later, the amount of the fluororesin (B) includes the alkali-soluble resin (D)). When the amount of the photopolymerization initiator is less than 0.1 parts by mass, the resulting crosslinking effect tends to be insufficient. When the amount thereof is more than 30 parts by mass, the resolution and sensitivity tend to decrease.

The photosensitive resin composition of the present disclosure preferably further contains an ethylenically unsaturated compound (C) and/or an alkali-soluble resin (D).

### <Ethylenically Unsaturated Compound (C)>

When the photosensitive resin composition of the present disclosure contains an ethylenically unsaturated compound (C), it is possible to promote the curing of the photosensitive resin composition by irradiation with light, allowing it to cure in a shorter time.

Specific examples of the ethylenically unsaturated compound (C) include polyfunctional acrylates (e.g., A-TMM-3, A-TMM-3L, A-TMM-3LM-N, A-TMPT, and AD-TMP (trade names) available from Shin-Nakamura Chemical Co., Ltd.); polyethylene glycol diacrylates (e.g., A-200, A-400, and A-600 (trade names) available from Shin-Nakamura Chemical Co., Ltd.); urethane acrylates (e.g., UA-122P, UA-4HA, UA-6HA, UA-6LPA, UA-11003H, UA-53H, UA-4200, UA-200PA, UA-33H, UA-7100, and UA-7200 (trade names) available from Shin-Nakamura Chemical Co., Ltd.); and pentaerythritol tetraacrylate.

The following are preferred examples of polyfunctional acrylate compounds.

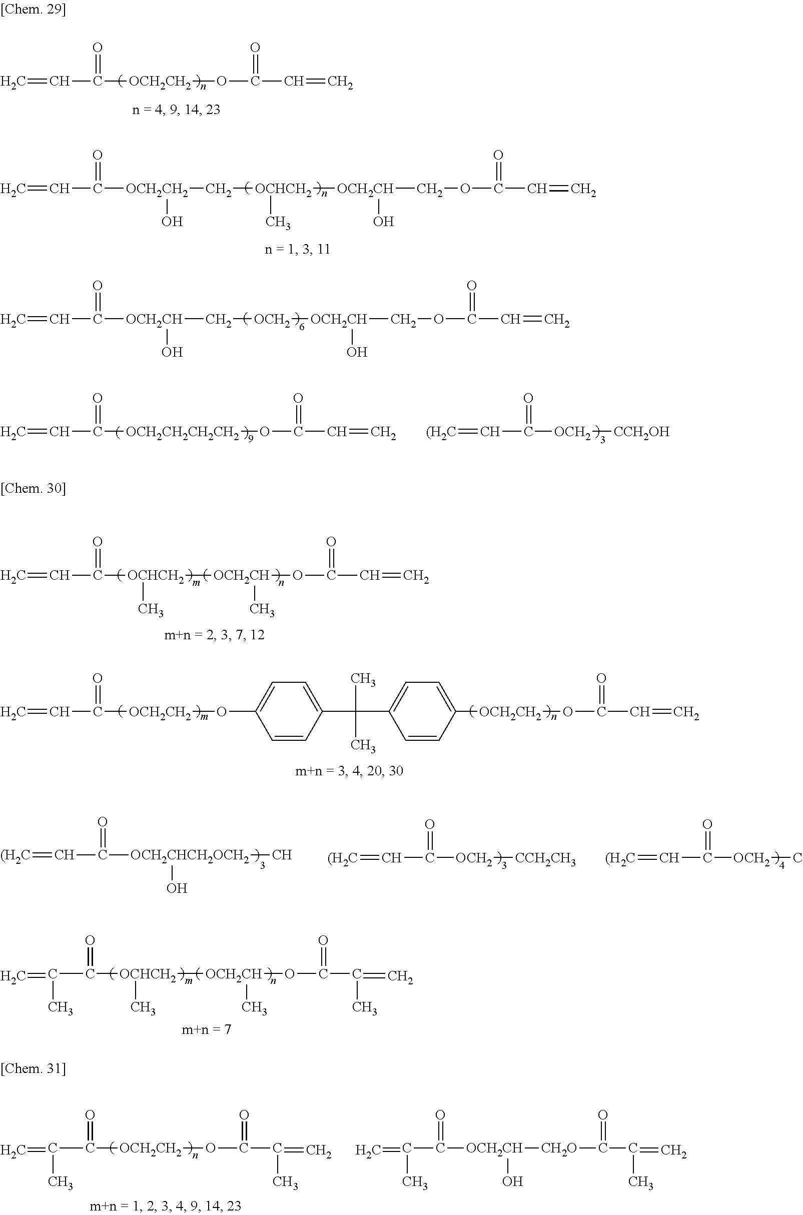

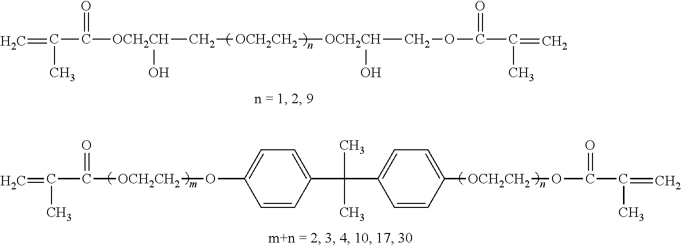

The amount of the ethylenically unsaturated compound (C) is preferably at least 10 parts by mass but not more than 300 parts by mass, more preferably at least 50 parts by mass but not more than 200 parts by mass, relative to 100 parts by mass of the concentration of the fluororesin (B) (provided that when the photosensitive resin composition contains the alkali-soluble resin (D) described later, the concentration of the fluororesin (B) includes the alkali-soluble resin (D)).

When the amount of the ethylenically unsaturated compound (C) is less than 10 parts by mass, the resulting crosslinking effect tends to be insufficient. When the amount thereof is more than 300 parts by mass, the resolution and sensitivity tend to decrease.

### <Alkali-Soluble Resin (D)>

When the photosensitive resin composition of the present disclosure contains an alkali-soluble resin (D), it is possible to improve the shape of the banks produced from the photosensitive resin composition of the present disclosure.

Examples of the alkali-soluble resin (D) include alkali-soluble novolac resins.

Alkali-soluble novolac resins can be produced by condensation of a phenol with an aldehyde in the presence of an acid catalyst.

Specific examples of the phenol include phenol, o-cresol, m-cresol, p-cresol, 2,3-dimethylphenol, 2,4-dimethylphenol, 2,5-dimethylphenol, 3,4-dimethylphenol, 3,5-dimethylphenol, 2,3,5-trimethylphenol, 3,4,5-trimethylphenol, resorcinol, 2-methylresorcinol, 4-ethylresorcinol, hydroquinone, methylhydroquinone, catechol, 4-methyl-catechol, pyrogallol, phloroglucinol, thymol, and isothymol. These phenols may be used alone or in combinations of two or more.

Specific examples of the aldehyde include formaldehyde, trioxane, paraformaldehyde, benzaldehyde, acetaldehyde, propylaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, nitrobenzaldehyde, furfural, glyoxal, glutaraldehyde, terephthalaldehyde, and isophthalaldehyde.

Specific examples of the acid catalyst include hydrochloric acid, nitric acid, sulfuric acid, phosphoric acid, phosphorous acid, formic acid, oxalic acid, acetic acid, methanesulfonic acid, diethyl sulfate, and p-toluenesulfonic acid. These acid catalysts may be used alone or in combinations of two or more.

Other examples of the alkali-soluble resin (D) include acid-modified epoxy acrylates. Examples of commercially available acid-modified epoxy acrylates include CCR-1218H, CCR-1159H, CCR-1222H, CCR-1291H, CCR-1235, PCR-1050, TCR-1335H, UXE-3024, ZAR-1035, ZAR-2001H, ZAR2051H, ZFR-1185, and ZCR-1569H (trade names) available from Nippon Kayaku Co., Ltd.

The mass average molecular weight of the alkali-soluble resin (D) component is preferably 1,000 to 50,000, from the standpoint of the developability and resolution of the photosensitive resin composition.

The amount of the alkali-soluble resin (D) in the photosensitive resin composition of the present disclosure is preferably at least 500 parts by mass but not more than 10,000 parts by mass, more preferably at least 1,000 parts by mass but not more than 7,000 parts by mass, relative to 100 parts by mass of the fluororesin (B). When the amount of the alkali-soluble resin (D) is more than 10,000 parts by mass, the resulting fluororesin of the present disclosure tends to have insufficient ink repellency after UV-ozone treatment or oxygen plasma treatment.

The photosensitive resin composition of the present disclosure preferably further contains at least one selected from the group consisting of a photo-radical sensitizer (E), a chain transfer agent (F), an ultraviolet absorber (G), and a polymerization inhibitor (H).

### <Photo-Radical Sensitizer (E)>

When the photosensitive resin composition of the present disclosure contains a photo-radical sensitizer (E), the photosensitive resin composition of the present disclosure can have further improved exposure sensitivity. The photo-radical sensitizer (E) is preferably a compound that is excited to an excited state by absorbing light rays or radiation. The photo-radical sensitizer (E) in an excited state, when contacted with a photopolymerization initiator, causes electron transfer, energy transfer, heat generation, or the like, which facilitates decomposition of the photopolymerization initiator to generate an acid. The photo-radical sensitizer (E) may have an absorption wavelength in the range of 350 nm to 450 nm. Examples include polynuclear aromatic compounds, xanthenes, xanthones, cyanines, merocyanines, thiazines, acridines, acridones, anthraquinones, squaryliums, styryls, base styryls, and coumarins.

Examples of the polynuclear aromatic compounds include pyrene, perylene, triphenylene, anthracene, 9,10-dibutoxyanthracene, 9,10-diethoxyanthracene, 3,7-dimethoxyanthracene, and 9,10-dipropyloxyanthracene.

Examples of the xanthenes include fluorescein, eosin, erythrosine, rhodamine B, and rose bengal.

Examples of the xanthones include xanthone, thioxanthone, dimethylthioxanthone, diethylthioxanthone, and isopropylthioxanthone.

Examples of the cyanines include thiacarbocyanine and oxacarbocyanine.

Examples of the merocyanines include merocyanine and carbomerocyanine.

Examples of the thiazines include thionine, methylene blue, and toluidine blue.

Examples of the acridines include acridine orange, chloroflavin, and acriflavine.

Examples of the acridones include acridone and 10-butyl-2-chloroacridone.

Examples of the anthraquinones include anthraquinone.

Examples of the squaryliums include squarylium.

Examples of the base styryls include 2-[2-[4-(dimethylamino)phenyl]ethenyl]benzoxazole.

Examples of the coumarins include 7-diethylamino-4-methylcoumarin, 7-hydroxy-4-methylcoumarin, and 2,3,6,7-tetrahydro-9-methyl-1H,5H,11H[1]benzopyrano[6,7,8-ij]quinolizin-11-one.

These photo-radical sensitizers (E) may be used alone or in combinations of two or more.

Preferred photo-radical sensitizers (E) for use in the photosensitive resin composition of the present disclosure are polynuclear aromatic compounds, acridones, styryls, base styryls, coumarins, and xanthones, with xanthones being particularly preferred, because they have a high exposure sensitivity-improving effect. Preferred of the xanthones are diethylthioxanthone and isopropylthioxanthone.

The amount of the photo-radical sensitizer (E) is preferably 0.1 parts by mass to 8 parts by mass, more preferably 1 part by mass to 4 parts by mass, relative to 100 parts by mass of the fluororesin (B). When the amount of the photo-radical sensitizer (E) is within the range indicated above, the photosensitive resin composition can have improved exposure sensitivity, and the patterned film obtained after exposure of the photosensitive resin composition of the present disclosure can have clear boundaries between the liquid-repellent and lyophilic portions, which improves the ink pattern contrast after ink application, resulting in a fine pattern.

### <Chain Transfer Agent (F)>

The photosensitive resin composition of the present disclosure preferably contains a chain transfer agent (F) if necessary.

Examples of the chain transfer agent (F) include the same compounds as those which can be used in the synthesis of the fluororesin (A) described above.

### <Ultraviolet Absorber (G)>

The photosensitive resin composition of the present disclosure preferably includes an ultraviolet absorber (G) if necessary. Examples of the ultraviolet absorber (G) include salicylic acid-based, benzophenone-based, and triazole-based ultraviolet absorbers.

The amount of the ultraviolet absorber (G) in the photosensitive resin composition is preferably 0.5 to 5 mass %, more preferably 1 to 3 mass %.

### <Polymerization Inhibitor (H)>

Non-limiting examples of the polymerization inhibitor (H) used in the photosensitive resin composition of the present disclosure include o-cresol, m-cresol, p-cresol, 6-t-butyl-2,4-xylenol, 2,6-di-t-butyl-p-cresol, hydroquinone, catechol, 4-t-butylpyrocatechol, 2,5-bistetramethylbutylhydroquinone, 2,5-di-t-butylhydroquinone, p-methoxyphenol, 1,2,4-trihydroxybenzene, 1,2-benzoquinone, 1,3-benzoquinone, 1,4-benzoquinone, leucoquinizarin, phenothiazine, 2-methoxyphenothiazine, tetraethylthiuram disulfide, 1,1-diphenyl-2-picrylhydrazyl, and 1,1-diphenyl-2-picrylhydrazine.

Examples of commercially available polymerization inhibitors (H) include N,N′-di-2-naphthyl-p-phenylenediamine (trade name, NONFLEX F), N,N-diphenyl-p-phenylenediamine (trade name, NONFLEX H), 4,4′-bis(a,a-dimethylbenzyl)diphenylamine (trade name, NONFLEX DCD), 2,2′-methylene-bis(4-methyl-6-tert-butylphenol) (trade name, NONFLEX MBP), and N-(1-methylheptyl)-N′-phenyl-p-phenylenediamine (trade name, OZONONE 35), all of which are available from Seiko Chemical Co., Ltd., and ammonium N-nitrosophenylhydroxyamine (trade name, Q-1300) and N-nitrosophenylhydroxyamine aluminum salt (trade name, Q-1301), both of which are available from FUJIFILM Wako Pure Chemical Corporation.

The percentage of the polymerization inhibitor (H) based on the total solids in the photosensitive resin composition of the present disclosure is preferably 0.001 to 20 mass %, more preferably 0.005 to 10 mass %, particularly preferably 0.01 to 5 mass %. When the percentage is within the above range, the development residues of the photosensitive resin composition can be reduced, resulting in good pattern linearity.

The photosensitive resin composition of the present disclosure may contain other additives if necessary. Examples of other additives include various additives such as dissolution inhibitors, plasticizers, stabilizers, colorants, thickeners, adhesives, and antioxidants. These other additives may be known ones.

A cured product of the present disclosure is obtained by curing the photosensitive resin composition. The photosensitive resin composition of the present disclosure can be formed into a film and exposed by known methods to provide a “resin film” which includes a cured product of a composition containing the fluororesin (B) as a main component. Specific methods for the film formation and the exposure are as described for the method of forming partition walls described later.

The resin film produced from the photosensitive resin composition of the present disclosure contains the above-described surface modifier and thus has improved surface roughness. The cured product of the present disclosure is preferably used as partition walls, particularly preferably partition walls of an organic EL display, a quantum dot display, or the like.

Next, a method of forming partition falls from the photosensitive resin composition of the present disclosure is described.

The method of forming partition walls may include (1) a film forming step, (2) an exposing step, and (3) a developing step.

Each step is described below.

### (1) Film Forming Step

First, the photosensitive resin composition of the present disclosure may be applied to a substrate, followed by heating to form the photosensitive resin composition into a fluororesin film.

The heating conditions are not limited, but are preferably at 80 to 100° C. for 60 to 200 seconds.

This can remove the solvents and the like from the photosensitive resin composition.

The substrate used may be, for example, a silicon wafer, metal, glass, or ITO substrate.

Moreover, an organic or inorganic film may be previously provided on the substrate. For example, the substrate may include an anti-reflective film or an underlayer of a multilayer resist, on which a pattern may be formed. The substrate may also be pre-washed. For example, the substrate may be washed with ultrapure water, acetone, alcohol (methanol, ethanol, or isopropyl alcohol), or other solvent.

A known method such as spin coating can be used to apply the photosensitive resin composition of the present disclosure to the substrate.

### (2) Exposing Step

Next, a desired photomask may be set in an exposure device, and the fluororesin film may be exposed to high energy rays through the photomask.

The high energy rays are preferably at least one type of rays selected from the group consisting of ultraviolet rays, gamma rays, X-rays, and α-rays.

The exposure of the high energy rays is preferably at least 1 mJ/cm 2 but not more than 200 mJ/cm 2, more preferably at least 10 mJ/cm 2 but not more than 100 mJ/cm 2.

### (3) Developing Step

Next, the fluororesin film obtained after the exposing step may be developed with an alkali aqueous solution to form a patterned fluororesin film.

Specifically, either the exposed or unexposed portions of the fluororesin film may be dissolved in an alkali aqueous solution to form a patterned fluororesin film.

The alkali aqueous solution used may be, for example, a tetramethylammonium hydroxide (TMAH) aqueous solution or a tetrabutylammonium hydroxide (TBAH) aqueous solution.

When the alkali aqueous solution is a tetramethylammonium hydroxide (TMAH) aqueous solution, the concentration thereof is preferably at least 0.1 mass % but not more than 5 mass %, more preferably at least 2 mass % but not more than 3 mass %.

Any known development method can be used, such as dipping, paddling, or spraying.

The development time (the duration during which the developer comes into contact with the fluororesin film) is preferably at least 10 seconds but not more than 3 minutes, more preferably at least 30 seconds but not more than 2 minutes.

The development may optionally be followed by a step of washing the patterned fluororesin film with deionized water or the like. Regarding the washing method and washing time, washing for at least 10 seconds but not more than 3 minutes is preferred, and washing for at least 30 seconds but not more than 2 minutes is more preferred.

The partition walls produced in this manner can be used as banks for a display.

A display of the present disclosure includes a luminescent element including: a partition wall obtained by curing the photosensitive resin composition of the present disclosure; and a luminescent layer or a wavelength conversion layer placed in a region partitioned by the partition wall.

Examples of the display include organic EL displays and quantum dot displays.

A method of modifying a surface of a molded article of the present disclosure includes a fluororesin (A) having a structure represented by the above formula (1).

The fluororesin (A) may be as described above for the surface modifier and the photosensitive resin composition.

The method of the present disclosure can modify surfaces of various resin molded articles. Modifying a surface of a molded article refers to reducing the occurrence of bubbles, brush marks, orange peel, cissing, craters, pinholes, floating, and various other coating film defects during resin molding or coating film formation. Reducing the occurrence of these coating film defects can improve, for example, surface roughness.

Any type of resin may be used as the material of the molded article, such as one or a combination of two or more of the following resins: olefin resins, epoxy resins, (meth)acrylic resins, urethane resins, fluororesins, etc. The method of the present disclosure can be particularly suitably used for preparing a molded article from a composition containing two or more resins differing in the amount of fluorine. The composition is particularly preferably a photosensitive resin composition.

In the method of the present disclosure, the fluororesin (A) can be mixed and used in a resin composition. The preferred embodiments and amount of the fluororesin (A) are as described above for the photosensitive resin composition.

The fluororesin (A) acts as a surface modifier or surfactant such as a defoamer, a leveling agent, or an anti-popping agent.

The present disclosure also encompasses the use of a fluororesin (A) having a structure represented by the above formula (1) for modifying a surface of a molded article.

### EXAMPLES

The present disclosure is described in detail below with reference to examples, but the present disclosure is not limited to these examples.

### (Measurement of Molar Ratio of Each Repeating Unit of Polymer)

The molar ratio of each repeating unit of the polymer was determined from the measurements of ¹H-NMR, ¹⁹F-NMR, or ¹³C-NMR.

### (Measurement of Molecular Weight of Polymer)

The weight average molecular weight Mw and molecular weight dispersity (Mw/Mn: the ratio of the weight average molecular weight Mw to the number average molecular weight Mn) of the polymer were measured by high performance gel permeation chromatography (hereinafter sometimes referred to as GPC; model: HLC-8320 GPC available from Tosoh Corporation) with one ALPHA-M column and one ALPHA-2500 column (both available from Tosoh Corporation) connected in series using polystyrene standards and tetrahydrofuran (THF) as a developing solvent. The detector used was a refractive index difference detector.

### 1. Synthesis of Fluororesin (B)

### Synthesis Example 1: Synthesis of Fluororesin B-1 Having Crosslinking Site

### Synthesis of Fluororesin Precursor 1

A 300 ml glass flask equipped with a stirrer was charged at room temperature (about 20° C.) with 4.3 g (0.02 mol) of 1,1-bis(trifluoromethyl)-1,3-butadiene (available from Central Glass Co., Ltd., hereinafter referred to as BTFBE), 2.7 g (0.02 mol) of 4-acetoxystyrene (available from Tokyo Chemical Industry Co., Ltd., hereinafter referred to as p-AcO-St), 21.4 g (0.07 mol) of 2-(perfluorobutyl)ethyl methacrylate (available from Tokyo Chemical Industry Co., Ltd., hereinafter referred to as MA-C4F), 6.1 g (0.05 mol) of 2-hydroxyethyl methacrylate (available from Tokyo Chemical Industry Co., Ltd., hereinafter referred to as HEMA), and 36.9 g of methyl ethyl ketone (hereinafter referred to as MEK). Then, 2.46 g (0.02 mol) of 2,2′-azobis(2-methylbutyronitrile) (available from Tokyo Chemical Industry Co., Ltd., hereinafter referred to as AIBN) was added and the mixture was degassed with stirring. Subsequently, the flask was purged with nitrogen gas, and the temperature inside the flask was raised to 79° C., followed by reaction overnight. To the reaction system was dropped 250 g of n-heptane, whereby a white precipitate was obtained. This precipitate was filtered out and dried under reduced pressure at a temperature of 45° C. to give 30.4 g of a fluororesin precursor 1 as a white solid with a yield of 88%.

### <NMR Measurement Results>

The ratio of each repeating unit of the fluororesin precursor 1, expressed as the molar ratio, was as follows: BTFBE-derived repeating unit:p-AcO-St-derived repeating unit:MA-C4F-derived repeating unit:HEMA-derived repeating unit=15:11:43:31.

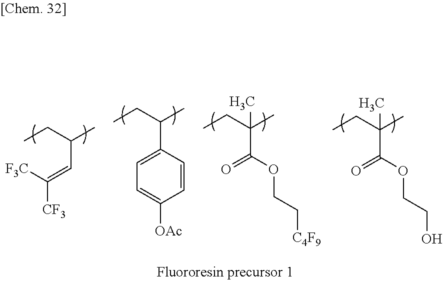

### <GPC Meausrement Results>

### Mw=7,201, Mw/Mn=1.4

### Synthesis of Fluororesin B-1 Having Crosslinking Site

A 100 ml glass flask equipped with a stirrer was charged with 10 g (hydroxy group equivalent: 0.01 mol) of the fluororesin precursor 1, 0.07 g (hydroxy group equivalent: 0.0007 mol) of triethylamine, and 20 g of PGMEA. Then, 1.51 g (hydroxy group equivalent: 0.01 mol) of Karenz AOI (2-isocyanatoethyl acrylate, available from Showa Denko K.K.) was added and the mixture was reacted at 45° C. for four hours. After completion of the reaction, the reaction solution was concentrated, and then 100 g of n-heptane was added to precipitate a precipitate. This precipitate was filtered out and dried under reduced pressure at 40° C. to give a fluororesin B-1 having a crosslinking site as a white solid with a yield of 75%.

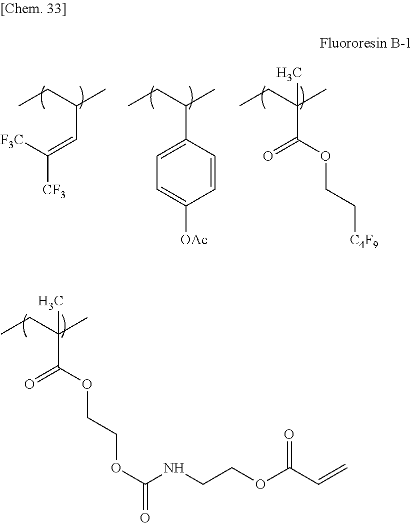

### <¹³C-NMR Measurement Results>

In the fluororesin B-1 having a crosslinking site, the ratio of the amount of the Karenz AOI-derived acrylic acid derivative introduced (reacted ratio) to the amount of residual hydroxy groups (unreacted ratio), expressed as the molar ratio, was 96:4. It was also found that the ratio of each repeating unit unreactive with the crosslinking site (BTFBE-derived repeating unit, p-AcO-St-derived repeating unit, MA-C4F-derived repeating unit) remained unchanged from that of the fluororesin precursor 1 used (i.e., the same as before the introduction of the crosslinking site).

### Synthesis Example 2: Synthesis of Fluororesin B-2 Having Crosslinking Site

### Synthesis of Fluororesin Precursor 2

A 300 ml glass flask equipped with a stirrer was charged at room temperature with 13.01 g (0.1 mol) of HEMA, 43.2 g (0.1 mol) of 2-(perfluorohexyl)ethyl methacrylate (available from Tokyo Chemical Industry Co., Ltd., hereinafter referred to as MA-C6F), 23.6 g (0.1 mol) of hexafluoroisopropyl methacrylate (available from Central Glass Co., Ltd., hereinafter referred to as HFIP-M), 8.66 g (0.1 mol) of methacrylic acid (available from Tokyo Chemical Industry Co., Ltd., hereinafter referred to as MAA), and 88 g of MEK. Then, 1.6 g (0.010 mol) of AIBN was added and the mixture was degassed with stirring. Subsequently, the flask was purged with nitrogen gas, and the temperature inside the flask was raised to 80° C., followed by reaction for six hours. After completion of the reaction, the reaction solution was dropped into 500 g of n-heptane, whereby a white precipitate was obtained. This precipitate was filtered out and dried under reduced pressure at a temperature of 60° C. to give 60 g of a fluororesin precursor 2 as a white solid with a yield of 68%.

### <NMR Measurement Results>

The ratio of each repeating unit of the fluororesin precursor 2, expressed as the molar ratio, was as follows: HEMA-derived repeating unit:MA-C6F-derived repeating unit:HFIP-M-derived repeating unit:MAA-derived repeating unit=24:26:24:26.

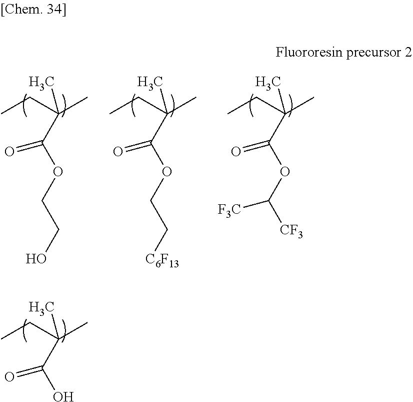

### <GPC Measurement Results>

### Mw=10,700, Mw/Mn=1.5

### Synthesis of Fluororesin B-2 Having Crosslinking Site

A fluororesin B-2 having a crosslinking site was obtained with a yield of 90% by the same procedure as in the synthesis of the fluororesin B-1 having a crosslinking site, except that the fluororesin precursor 2 was used instead of the fluororesin precursor 1.

### <¹³C-NMR Measurement Results>

In the fluororesin B-2 having a crosslinking site, the ratio of the amount of the Karenz AOI-derived acrylic acid derivative introduced (reacted ratio) to the amount of residual hydroxy groups (unreacted ratio), expressed as the molar ratio, was 96:4. It was also found that the ratio of each repeating unit unreactive with the crosslinking site (MA-C6F-derived repeating unit, HFIP-M-derived repeating unit) remained unchanged from that of the fluororesin precursor 2 used (i.e., the same as before the introduction of the crosslinking group).

### 2. Synthesis of Fluororesin (A) for Surface Modifier

### Example 1

### Synthesis of Fluororesin A-1

A 100 ml glass flask equipped with a stirrer was charged at room temperature (about 20° C.) with 11.8 g (0.04 mol) of 5,5,5-trifluoro-4-hydroxy-4-(trifluoromethyl)pentan-2-yl methacrylate (available from Central Glass Co., Ltd., hereinafter referred to as MA-BTHB-OH) and 24 g of MEK. Then, 0.65 g (0.004 mol) of AIBN (available from Tokyo Chemical Industry Co., Ltd.) was added and the mixture was degassed with stirring. Subsequently, the flask was purged with nitrogen gas, and the temperature inside the flask was raised to 79° C., followed by reaction for six hours. To the reaction system was dropped 200 g of n-heptane, whereby a white precipitate was obtained. This precipitate was filtered out and dried under reduced pressure at a temperature of 45° C. to give 8.47 g of a fluororesin A-1 as a white solid with a yield of 72%.

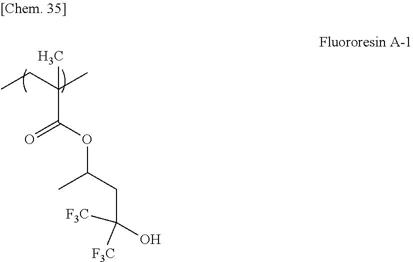

### <GPC Measurement Resuts>

### Mw=13,370, Mw/Mn=1.9

### Example 2

### Synthesis of Fluororesin A-2

A fluororesin A-2 was obtained with a yield of 68% by the same procedure as in the synthesis of the fluororesin A-1, except that the temperature inside the flask was raised to 85° C.

<GPC measurement results>

### Mw=8770, Mw/Mn=1.6

### Example 3

### Synthesis of Fluororesin A-3

A fluororesin A-3 was obtained with a yield of 87% by the same procedure as in the synthesis of the fluororesin A-1, except that 0.16 g (0.001 mol) of AIBN (available from Tokyo Chemical Industry Co., Ltd.) was used.

<GPC measurement results>

### Mw=38,400, Mw/Mn=2.3

### Example 4

### Synthesis of Fluororesin A-4

A fluororesin A-4 was obtained with a yield of 84% by the same procedure as in the synthesis of the fluororesin A-1, except that 3,5-bis(1,1,1,3,3,3-hexafluoro-2-hydroxy-2-propanyl)cyclohexyl methacrylate (available from Central Glass Co., Ltd.) was used instead of MA-BTHB-OH.

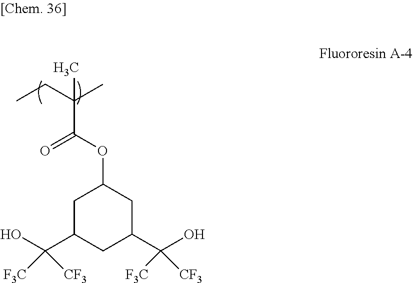

### <GPC Measurement Resuts>

### Mw=14,800, Mw/Mn=1.9

### Example 5

### Synthesis of Fluororesin A-5

A fluororesin A-5 was obtained with a yield of 82% by the same procedure as in the synthesis of the fluororesin A-1, except that 1,3-bis(1,1,1,3,3,3-hexafluoro-2-hydroxy-2-propanyl)isopropyl methacrylate (available from Central Glass Co., Ltd., hereinafter referred to as MA-BTHB-HFA) was used instead of MA-BTHB-OH.

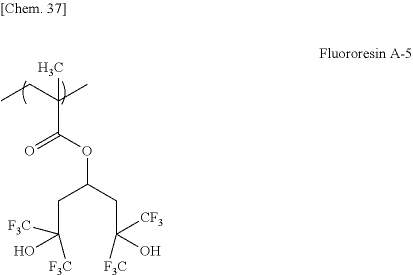

### Mw=11,800, Mw/Mn=1.5

### Example 6

### Synthesis of Fluororesin A-6

A 300 ml glass flask equipped with a stirrer was charged at room temperature (about 20° C.) with 13.86 g (0.3 mol) of MA-BTHB-HFA, 2.36 g (0.1 mol) of HFIP-M, and 32 g of MEK. Then, 0.25 g (0.002 mol) of AIBN (available from Tokyo Chemical Industry Co., Ltd.) was added and the mixture was degassed with stirring. Subsequently, the flask was purged with nitrogen gas, and the temperature inside the flask was raised to 79° C., followed by reaction overnight. To the reaction system was dropped 200 g of n-heptane, whereby a white precipitate was obtained. This precipitate was filtered out and dried under reduced pressure at a temperature of 50° C. to give 13 g of a fluororesin A-6 as a white solid with a yield of 80%.

### <NMR Measurement Results>

The ratio of each repeating unit of the fluororesin A-6, expressed as the molar ratio, was as follows: MA-BTHB-HFA-derived repeating unit:HFIP-M-derived repeating unit=75:25.

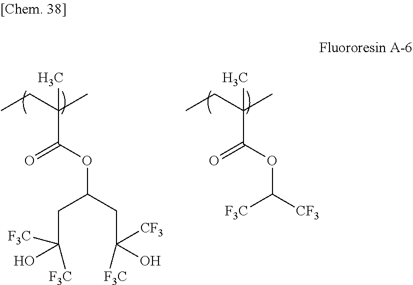

<GPC measurement results>

### Mw=12,300, Mw/Mn=1.6

### Example 7

### Synthesis of Fluororesin A-7

A fluororesin A-7 was obtained with a yield of 81% by the same procedure as in the synthesis of the fluororesin A-6, except that butyl methacrylate (reagent available from Tokyo Chemical Industry Co., Ltd.) was used instead of HFIP-M.

### <NMR Measurement Results>

The ratio of each repeating unit of the fluororesin A-7, expressed as the molar ratio, was as follows: MA-BTHB-HFA-derived repeating unit:butyl methacrylate-derived repeating unit=75:25.

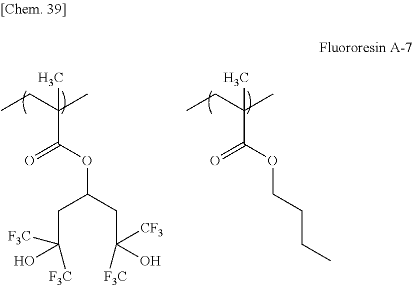

### <GPC Measurement Resuts>

### Mw=11,300, Mw/Mn=1.5

### Example 8

### Synthesis of Fluororesin A-8

A fluororesin A-8 was obtained with a yield of 79% by the same procedure as in the synthesis of the fluororesin A-6, except that the amount of MA-BTHB-HFA was changed to 4.62 g (0.1 mol) and the amount of HFIP-M was changed to 7.08 g (0.3 mol).

### <NMR Measurement Results>

The ratio of each repeating unit of the fluororesin A-8, expressed as the molar ratio, was as follows: MA-BTHB-HFA-derived repeating unit:HFIP-M-derived repeating unit=25:75.

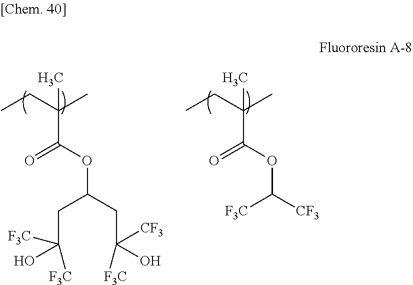

### <GPC Measurement Resuts>

### Mw=13,000, Mw/Mn=1.7

### Example 9

### Synthesis of Fluororesin A-9

A fluororesin A-9 was obtained with a yield of 82% by the same procedure as in the synthesis of the fluororesin A-6, except that the amount of MA-BTHB-HFA was changed to 9.24 g (0.2 mol) and the amount of HFIP-M was changed to 4.72 g (0.2 mol).

### <NMR Measurement Results>

The ratio of each repeating unit of the fluororesin A-9, expressed as the molar ratio, was as follows: MA-BTHB-HFA-derived repeating unit:HFIP-M-derived repeating unit=50:50.

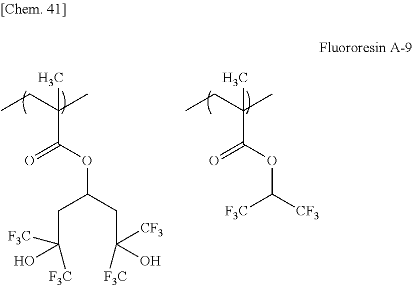

### <GPC Measurement Resuts>

### Mw=12,500, Mw/Mn=1.6

### Example 10

### Synthesis of Fluororesin A-10

A 300 ml glass flask equipped with a stirrer was charged at room temperature (about 20° C.) with 14.62 g (0.1 mol) of MA-BTHB-HFA, 2.36 g (0.1 mol) of HFIP-M, 1.42 g (0.1 mol) of butyl methacrylate, and 36 g of MEK. Then, 0.25 g (0.002 mol) of AIBN (available from Tokyo Chemical Industry Co., Ltd.) was added and the mixture was degassed with stirring. Subsequently, the flask was purged with nitrogen gas, and the temperature inside the flask was raised to 79° C., followed by reaction overnight. To the reaction system was dropped 200 g of n-heptane, whereby a white precipitate was obtained. This precipitate was filtered out and dried under reduced pressure at a temperature of 50° C. to give 14 g of a fluororesin A-10 as a white solid with a yield of 76%.

### <NMR Measurement Results>

The ratio of each repeating unit of the fluororesin A-10, expressed as the molar ratio, was as follows: MA-BTHB-HFA-derived repeating unit:HFIP-M-derived repeating unit:butyl methacrylate-derived repeating unit=1:1:1.

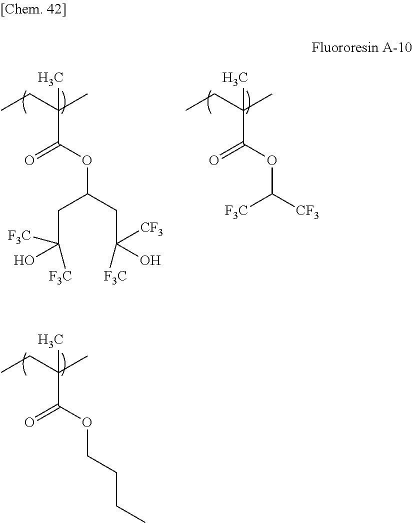

### <GPC Measurement Results>

### Mw=13,800, Mw/Mn=1.8

### Comparative Example 1

### Synthesis of Comparative Fluororesin A-1

A comparative fluororesin A-1 was obtained with a yield of 81% by the same procedure as in the synthesis of the fluororesin A-1, except that HFIP-M (available from Central Glass Co., Ltd.) was used instead of MA-BTHB-OH.

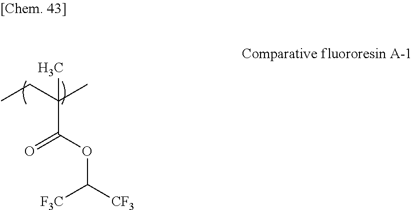

### <GPC Measurement Resuts>

### Mw=12,123, Mw/Mn=1.8

### Comparative Example 2

### Synthesis of Comparative Fluororesin A-2

A 100 ml glass flask equipped with a stirrer was charged at room temperature (about 20° C.) with 16.6 g (0.07 mol) of HFIP-M (available from Central Glass Co., Ltd.), 4.0 g (0.03 mol) of HEMA (available from Tokyo Chemical Industry Co., Ltd.), and 20 g of MEK. Then, 0.17 g (0.001 mol) of AIBN (available from Tokyo Chemical Industry Co., Ltd.) was added and the mixture was degassed with stirring. Subsequently, the flask was purged with nitrogen gas, and the temperature inside the flask was raised to 80° C., followed by reaction overnight. To the reaction system was dropped 160 g of n-heptane, whereby a white precipitate was obtained. This precipitate was filtered out and dried under reduced pressure at a temperature of 45° C. to give 17.0 g of a comparative fluororesin A-2 as a white solid with a yield of 83%.

### <NMR Measurement Results>

The ratio of each repeating unit of the comparative fluororesin A-2, expressed as the molar ratio, was as follows: HFIP-M-derived repeating unit:HEMA-derived repeating unit=70:30.

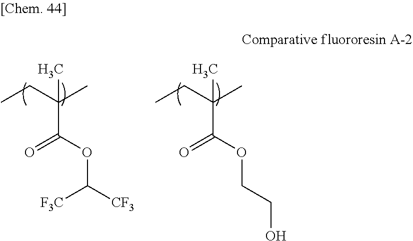

### <GPC Measurement Results>

### Mw=14,289, Mw/Mn=1.7

### 3. Preparation of Photosensitive Resin Composition

### Comparative Example 3

### (Preparation of Photosensitive Resin Composition 1)

An amount of 0.5 parts by mass of the produced fluororesin B-1 having a crosslinking site, 0.5 parts by mass of IRGACURE 369 (2-benzyl-2-dimethylamino-1-(4-morpholinophenyl)-butan-1-one, product of BASF) as a polymerization initiator, 50 parts by mass of pentaerythritol tetraacrylate (product of Tokyo Chemical Industry Co., Ltd.) as a crosslinking agent, 50 parts by mass of ZAR2051H (bisphenol A-based epoxy acrylate, product of Nippon Kayaku Co., Ltd.) as an alkali-soluble resin, and 160 parts by mass of propylene glycol monomethyl ether acetate (PGMEA) and 70 parts by mass of propylene glycol monomethyl ether (PGME) as solvents were blended. The resulting solution was filtered through a 0.2 μm membrane filter to prepare a photosensitive resin composition 1.

### Example 11

### (Preparation of Photosensitive Resin Composition 1-1)

The fluororesin A-1 obtained in “2. Synthesis of fluororesin for surface modifier” was added and dissolved into the above-prepared photosensitive resin composition 1 at the percentage (mass %) relative to the total solids of the photosensitive resin composition 1 as shown in Table 1. Subsequently, the resulting solution was filtered through a 0.2 μm membrane filter to prepare a photosensitive resin composition 1-1.

### Example 12

### (Preparation of Photosensitive Resin Composition 1-2)

A photosensitive resin composition 1-2 was prepared by the same procedure as in the preparation of the photosensitive resin composition 1-1, except that the fluororesin A-2 was used instead of the fluororesin A-1.

### Example 13

### (Preparation of Photosensitive Resin Composition 1-3)

A photosensitive resin composition 1-3 was prepared by the same procedure as in the preparation of the photosensitive resin composition 1-1, except that the fluororesin A-3 was used instead of the fluororesin A-1.

### Example 14

### (Preparation of Photosensitive Resin Composition 1-4)

A photosensitive resin composition 1-4 was prepared by the same procedure as in the preparation of the photosensitive resin composition 1-1, except that the fluororesin A-4 was used instead of the fluororesin A-1.

### Example 15

### (Preparation of Photosensitive Resin Composition 1-5)

A photosensitive resin composition 1-5 was prepared by the same procedure as in the preparation of the photosensitive resin composition 1-1, except that the fluororesin A-5 was used instead of the fluororesin A-1.

### Example 16

### (Preparation of Photosensitive Resin Composition 1-6)

A photosensitive resin composition 1-6 was prepared by the same procedure as in the preparation of the photosensitive resin composition 1-1, except that the fluororesin A-6 was used instead of the fluororesin A-1.

### Example 17

### (Preparation of Photosensitive Resin Composition 1-7)

A photosensitive resin composition 1-7 was prepared by the same procedure as in the preparation of the photosensitive resin composition 1-1, except that the fluororesin A-7 was used instead of the fluororesin A-1.

### Example 18

### (Preparation of Photosensitive Resin Composition 1-8)

A photosensitive resin composition 1-8 was prepared by the same procedure as in the preparation of the photosensitive resin composition 1-1, except that the fluororesin A-8 was used instead of the fluororesin A-1.

### Example 19

### (Preparation of Photosensitive Resin Composition 1-9)

A photosensitive resin composition 1-9 was prepared by the same procedure as in the preparation of the photosensitive resin composition 1-1, except that the fluororesin A-9 was used instead of the fluororesin A-1.

### Example 20

### (Preparation of Photosensitive Resin Composition 1-10)

A photosensitive resin composition 1-10 was prepared by the same procedure as in the preparation of the photosensitive resin composition 1-1, except that the fluororesin A-10 was used instead of the fluororesin A-1.

### Comparative Example 4

### (Preparation of Comparative Photosensitive Resin Composition 1-1)

A comparative photosensitive resin composition 1-1 was prepared by the same procedure as in the preparation of the photosensitive resin composition 1-1, except that the comparative fluororesin A-1 was used instead of the fluororesin A-1.

### Comparative Example 5

### (Preparation of Comparative Photosensitive Resin Composition 1-2)

A comparative photosensitive resin composition 1-2 was prepared by the same procedure as in the preparation of the photosensitive resin composition 1-1, except that the comparative fluororesin A-2 was used instead of the fluororesin A-1.

### Comparative Example 6

### (Preparation of Photosensitive Resin Composition 2)

An amount of 0.5 parts by mass of the produced fluororesin B-2 having a crosslinking site, 0.5 parts by mass of IRGACURE 369 as a polymerization initiator, 50 parts by mass of pentaerythritol tetraacrylate as a crosslinking agent, 50 parts by mass of ZAR2051H as an alkali-soluble resin, and 160 parts by mass of PGMEA and 70 parts by mass of PGME as solvents were blended. The resulting solution was filtered through a 0.2 μm membrane filter to prepare a photosensitive resin composition 2.

### Example 21

### (Preparation of Photosensitive Resin Composition 2-1)

The fluororesin A-1 obtained in “2. Synthesis of fluororesin for surface modifier” was added and dissolved into the above-prepared photosensitive resin composition 2 at the percentage (mass %) relative to the total solids of the photosensitive resin composition 2 as shown in Table 1. Subsequently, the resulting solution was filtered through a 0.2 μm membrane filter to prepare a photosensitive resin composition 2-1.

### Example 22

### (Preparation of Photosensitive Resin Composition 2-2)

A photosensitive resin composition 2-2 was prepared by the same procedure as in the preparation of the photosensitive resin composition 2-1, except that the fluororesin A-2 was used instead of the fluororesin A-1.

### Example 23

### (Preparation of Photosensitive Resin Composition 2-3)

A photosensitive resin composition 2-3 was prepared by the same procedure as in the preparation of the photosensitive resin composition 2-1, except that the fluororesin A-3 was used instead of the fluororesin A-1.

### Example 24

### (Preparation of Photosensitive Resin Composition 2-4)

A photosensitive resin composition 2-4 was prepared by the same procedure as in the preparation of the photosensitive resin composition 2-1, except that the fluororesin A-4 was used instead of the fluororesin A-1.

### Example 25

### (Preparation of Photosensitive Resin Composition 2-5)

A photosensitive resin composition 2-5 was prepared by the same procedure as in the preparation of the photosensitive resin composition 2-1, except that the fluororesin A-5 was used instead of the fluororesin A-1.

### Example 26

(Preparation of photosensitive resin composition 2-6)

A photosensitive resin composition 2-6 was prepared by the same procedure as in the preparation of the photosensitive resin composition 2-1, except that the fluororesin A-6 was used instead of the fluororesin A-1.

### Example 27

### (Preparation of Photosensitive Resin Composition 2-7)

A photosensitive resin composition 2-7 was prepared by the same procedure as in the preparation of the photosensitive resin composition 2-1, except that the fluororesin A-7 was used instead of the fluororesin A-1.

### Example 28

### (Preparation of Photosensitive Resin Composition 2-8)

A photosensitive resin composition 2-8 was prepared by the same procedure as in the preparation of the photosensitive resin composition 2-1, except that the fluororesin A-8 was used instead of the fluororesin A-1.

### Example 29

### (Preparation of Photosensitive Resin Composition 2-9)

A photosensitive resin composition 2-9 was prepared by the same procedure as in the preparation of the photosensitive resin composition 2-1, except that the fluororesin A-9 was used instead of the fluororesin A-1.

### Example 30

### (Preparation of Photosensitive Resin Composition 2-10)

A photosensitive resin composition 2-10 was prepared by the same procedure as in the preparation of the photosensitive resin composition 2-1, except that the fluororesin A-10 was used instead of the fluororesin A-1.

### Comparative Example 7

### (Preparation of Comparative Photosensitive Resin Composition 2-1)

A comparative photosensitive resin composition 2-1 was prepared by the same procedure as in the preparation of the photosensitive resin composition 2-1, except that the comparative fluororesin A-1 was used instead of the fluororesin A-1.

### Comparative Example 8

### (Preparation of Comparative Photosensitive Resin Composition 2-2)

A comparative photosensitive resin composition 2-2 was prepared by the same procedure as in the preparation of the photosensitive resin composition 2-1, except that the comparative fluororesin A-2 was used instead of the fluororesin A-1.

### 4. Evaluation of Surface Roughness

The photosensitive resin compositions 1, 1-1 to 1-10, 2, and 2-1 to 2-10 and comparative photosensitive resin compositions 1-1 to 1-2 and 2-1 to 2-2 obtained in “3. Preparation of photosensitive resin composition” were each used to form a resin film and subjected to evaluation and comparison of the surface roughness. Table 1 shows the results.

### (Formation of Resin Film)

A 10 cm square alkali-free substrate was washed with ultrapure water and then acetone. Subsequently, the substrate was subjected to UV-ozone treatment for five minutes using a UV-ozone treatment device (available from Sen Lights Corporation, model number: PL17-110). Then, the photosensitive resin compositions 1, 1-1 to 1-10, 2, and 2-1 to 2-10 and comparative photosensitive resin compositions 1-1 to 1-2 and 2-1 to 2-2 obtained in “3. Preparation of photosensitive resin composition” were each applied to the resulting UV-ozone-treated substrate using a spin coater at a rotation speed of 1,000 rpm, followed by heating on a hot plate at 100° C. for 150 seconds. Thus, fluororesin films and comparative fluororesin films each having a thickness of 2 μm were formed. The resulting resin films were each exposed by irradiation with i-rays (wavelength 365 nm).

Each resulting exposed resin film was heated at 230° C. for 60 minutes, and then the entire surface of the substrate was cooled. Subsequently, each substrate was measured at ten points within a 1 mm square area using a laser microscope (VX-1100 available from Keyence Corporation) at an objective lens magnification of 150×, and the arithmetic average roughness was calculated to evaluate the surface roughness.

TABLE 1

| | Photosensitive | | Surface | | Photosensitive | | Surface |
|---|---|---|---|---|---|---|---|
| | resin | Fluororesin (A) | roughness | | resin | Fluororesin (A) | roughness |
| | composition | (mass %) | (nm) | | composition | (mass %) | (nm) |
| Comparative | 1 | 0 | 90 | Comparative | 2 | 0 | 110 |
| Example 3 | | | | Example 6 | | | |
| Example 11 | 1-1 | 0.02 | 40 | Example 21 | 2-1 | 0.02 | 50 |
| | | 0.2 | 10 | | | 0.2 | 20 |
| | | 2 | 10 | | | 2 | 10 |
| | | 3 | 40 | | | 3 | 40 |
| Example 12 | 1-2 | 0.1 | 30 | Example 22 | 2-2 | 0.1 | 20 |
| | | 1 | 10 | | | 1 | 10 |
| | | 2 | 10 | | | 2 | 10 |
| Example 13 | 1-3 | 0.1 | 50 | Example 23 | 2-3 | 0.1 | 60 |
| | | 1 | 30 | | | 1 | 20 |
| | | 2 | 40 | | | 2 | 40 |
| Example 14 | 1-4 | 0.1 | 20 | Example 24 | 2-4 | 0.1 | 30 |
| | | 1 | 10 | | | 1 | 20 |
| | | 2 | 10 | | | 2 | 20 |
| Example 15 | 1-5 | 0.1 | 20 | Example 25 | 2-5 | 0.1 | 20 |
| | | 1 | 10 | | | 1 | 10 |
| | | 2 | 10 | | | 2 | 10 |
| Example 16 | 1-6 | 0.1 | 30 | Example 26 | 2-6 | 0.1 | 40 |
| | | 1 | 20 | | | 1 | 30 |
| | | 2 | 10 | | | 2 | 40 |
| Example 17 | 1-7 | 0.1 | 20 | Example 27 | 2-7 | 0.1 | 30 |
| | | 1 | 10 | | | 1 | 20 |
| | | 2 | 10 | | | 2 | 30 |
| Example 18 | 1-8 | 0.1 | 30 | Example 28 | 2-8 | 0.1 | 40 |
| | | 1 | 10 | | | 1 | 20 |
| | | 2 | 20 | | | 2 | 20 |
| Example 19 | 1-9 | 0.1 | 30 | Example 29 | 2-9 | 0.1 | 40 |
| | | 1 | 20 | | | 1 | 30 |
| | | 2 | 20 | | | 2 | 30 |
| Example 20 | 1-10 | 0.1 | 30 | Example 30 | 2-10 | 0.1 | 30 |
| | | 1 | 10 | | | 1 | 10 |
| | | 2 | 20 | | | 2 | 20 |
| Comparative | Comparative 1-1 | 0.1 | 90 | Comparative | Comparative 2-1 | 0.1 | 100 |
| Example 4 | | 1 | 100 | Example 7 | | 1 | 120 |
| | | 2 | 110 | | | 2 | 120 |
| Comparative | Comparative 1-2 | 0.1 | 100 | Comparative | Comparative 2-2 | 0.1 | 110 |
| Example 5 | | 1 | 110 | Example 8 | | 1 | 120 |
| | | 2 | 120 | | | 2 | 130 |

As shown in Table 1, the resin films produced from the photosensitive resin compositions of the comparative examples had a surface roughness of 90 nm or more, whereas all the resin films produced from the photosensitive resin compositions of the examples had a surface roughness of 10 to 60 nm, demonstrating that the examples were significantly better than the comparative examples.

### 5. Evaluation of Banks

The photosensitive resin compositions 1, 1-1 to 1-10, 2, and 2-1 to 2-10 and comparative photosensitive resin compositions 1-1 to 1-2 and 2-1 to 2-2 obtained in “3. Preparation of photosensitive resin composition” were each used to form banks and subjected to evaluation and comparison of the bank properties. Tables 2 and 3 show the results of the banks of the present disclosure and the comparative banks.

### (Formation of Banks)

A 10 cm square ITO substrate was washed with ultrapure water and then acetone. Subsequently, the substrate was subjected to UV-ozone treatment for five minutes using a UV-ozone treatment device as described above. Then, the photosensitive resin compositions 1, 1-1 to 1-10, 2, and 2-1 to 2-10 and comparative photosensitive resin compositions 1-1 to 1-2 and 2-1 to 2-2 obtained in “3. Preparation of photosensitive resin composition” were each applied to the resulting UV-ozone-treated substrate using a spin coater at a rotation speed of 1,000 rpm, followed by heating on a hot plate at 100° C. for 150 seconds. Thus, fluororesin films and comparative fluororesin films each having a thickness of 2 μm were formed. The resulting resin films were each exposed by irradiation with i-rays (wavelength: 365 nm) using a mask aligner (available from SUSS MicroTec) with a mask having a 5 μm line-and-space pattern.

The resulting exposed resin films were subjected to evaluation of the developer solubility and the bank properties (sensitivity and resolution) and measurement of the contact angle.

### (Developer Solubility)

Each exposed resin film on the ITO substrate was immersed in an alkali developer at room temperature for 80 seconds to evaluate the solubility in the alkali developer. The alkali developer used was a 2.38 mass % tetramethylammonium hydroxide aqueous solution (hereinafter sometimes referred to as TMAH). The solubility of the banks was evaluated by measuring the film thickness of the banks after the immersion using a contact film thickness meter. The banks were deemed “soluble” if they were completely dissolved, and “insoluble” if they remained undissolved.

### (Bank Properties (Sensitivity and Resolution))

The optimal exposure Eop (mJ/cm 2) for forming banks in the aforementioned line-and-space pattern was determined and used as an index of sensitivity.

Moreover, the resulting pattern of banks was observed under a microscope to evaluate the resolution. The pattern was rated as “excellent” with no visible line-edge roughness, “good” with slightly visible line-edge roughness, and “not acceptable” with significant line-edge roughness.

### (Contact Angle)

Each substrate with banks obtained by the above process was heated at 230° C. for 60 minutes, and then the anisole contact angle of the surface of the banks was measured.

### (Surface Roughness)

The surface roughness of the banks was evaluated using a laser microscope. The laser microscope used was VX-1100 available from Keyence Corporation. The evaluation was performed as in the evaluation of the surface roughness of the resin films.

TABLE 2

| | Photosensitive | | Developer solubility | | Bank properties | | Anisole contact angle (°) | | Surface |
|---|---|---|---|---|---|---|---|---|---|
| | resin | Fluororesin (A) | Unexposed | Exposed | Sensitivity | | Unexposed | Exposed | roughness |
| | composition | (mass %) | portions | portions | (mJ/cm²) | Resolution | portions | portions | (nm) |
| Comparative | 1 | 0 | Soluble | Insoluble | 102 | Excellent | 10 | 65 | 100 |
| Example 3 | | | | | | | | | |
| Example 11 | 1-1 | 0.02 | Soluble | Insoluble | 102 | Excellent | 10 | 66 | 50 |
| | | 0.2 | Soluble | Insoluble | 102 | Excellent | 10 | 65 | 10 |
| | | 2 | Soluble | Insoluble | 102 | Excellent | 10 | 66 | 10 |
| | | 3 | Soluble | Insoluble | 102 | Excellent | 10 | 66 | 50 |
| Example 12 | 1-2 | 0.1 | Soluble | Insoluble | 105 | Excellent | 10 | 65 | 30 |
| | | 1 | Soluble | Insoluble | 103 | Excellent | 10 | 66 | 10 |
| | | 2 | Soluble | Insoluble | 102 | Excellent | 10 | 65 | 10 |
| Example 13 | 1-3 | 0.1 | Soluble | Insoluble | 105 | Excellent | 10 | 66 | 50 |
| | | 1 | Soluble | Insoluble | 102 | Excellent | 10 | 65 | 30 |
| | | 2 | Soluble | Insoluble | 105 | Excellent | 10 | 65 | 60 |
| Example 14 | 1-4 | 0.1 | Soluble | Insoluble | 102 | Excellent | 10 | 65 | 20 |
| | | 1 | Soluble | Insoluble | 105 | Excellent | 10 | 65 | 10 |
| | | 2 | Soluble | Insoluble | 103 | Excellent | 10 | 66 | 10 |
| Example 15 | 1-5 | 0.1 | Soluble | Insoluble | 100 | Excellent | 10 | 65 | 20 |
| | | 1 | Soluble | Insoluble | 100 | Excellent | 10 | 65 | 10 |
| | | 2 | Soluble | Insoluble | 101 | Excellent | 10 | 65 | 10 |
| Example 16 | 1-6 | 0.1 | Soluble | Insoluble | 102 | Excellent | 10 | 65 | 40 |
| | | 1 | Soluble | Insoluble | 102 | Excellent | 10 | 66 | 40 |
| | | 2 | Soluble | Insoluble | 103 | Excellent | 10 | 66 | 50 |
| Example 17 | 1-7 | 0.1 | Soluble | Insoluble | 102 | Excellent | 10 | 66 | 30 |
| | | 1 | Soluble | Insoluble | 104 | Excellent | 10 | 66 | 10 |
| | | 2 | Soluble | Insoluble | 103 | Excellent | 10 | 66 | 10 |
| Example 18 | 1-8 | 0.1 | Soluble | Insoluble | 105 | Excellent | 10 | 65 | 50 |
| | | 1 | Soluble | Insoluble | 104 | Excellent | 10 | 65 | 30 |
| | | 2 | Soluble | Insoluble | 104 | Excellent | 10 | 66 | 30 |
| Example 19 | 1-9 | 0.1 | Soluble | Insoluble | 104 | Excellent | 10 | 65 | 40 |
| | | 1 | Soluble | Insoluble | 105 | Excellent | 10 | 66 | 30 |
| | | 2 | Soluble | Insoluble | 103 | Excellent | 10 | 66 | 30 |
| Example 20 | 1-10 | 0.1 | Soluble | Insoluble | 103 | Excellent | 10 | 65 | 30 |
| | | 1 | Soluble | Insoluble | 102 | Excellent | 10 | 65 | 20 |
| | | 2 | Soluble | Insoluble | 103 | Excellent | 10 | 65 | 20 |
| Comparative | Comparative 1-1 | 0.1 | Soluble | Insoluble | 102 | Excellent | 10 | 66 | 100 |
| Example 4 | | 1 | Soluble | Insoluble | 105 | Excellent | 10 | 65 | 110 |
| | | 2 | Soluble | Insoluble | 103 | Excellent | 10 | 65 | 100 |
| Comparative | Comparative 1-2 | 0.1 | Soluble | Insoluble | 105 | Excellent | 10 | 65 | 110 |
| Example 5 | | 1 | Soluble | Insoluble | 102 | Excellent | 10 | 66 | 110 |
| | | 2 | Soluble | Insoluble | 102 | Excellent | 10 | 65 | 120 |

TABLE 3

| | Photosensitive | | Developer solubility | | Bank properties | | Anisole contact angle (°) | | Surface |
|---|---|---|---|---|---|---|---|---|---|
| | resin | Fluororesin (A) | Unexposed | Exposed | Sensitivity | | Unexposed | Exposed | roughness |
| | composition | (mass %) | portions | portions | (mJ/cm²) | Resolution | portions | portions | (nm) |
| Comparative | 2 | 0 | Soluble | Insoluble | 103 | Excellent | 10 | 62 | 120 |
| Example 6 | | | | | | | | | |
| Example 21 | 2-1 | 0.02 | Soluble | Insoluble | 103 | Excellent | 10 | 63 | 70 |
| | | 0.2 | Soluble | Insoluble | 103 | Excellent | 10 | 62 | 20 |
| | | 2 | Soluble | Insoluble | 103 | Excellent | 10 | 62 | 20 |
| | | 3 | Soluble | Insoluble | 102 | Excellent | 10 | 62 | 60 |
| Example 22 | 2-2 | 0.1 | Soluble | Insoluble | 103 | Excellent | 10 | 63 | 30 |
| | | 1 | Soluble | Insoluble | 102 | Excellent | 10 | 63 | 10 |
| | | 2 | Soluble | Insoluble | 105 | Excellent | 10 | 62 | 10 |
| Example 23 | 2-3 | 0.1 | Soluble | Insoluble | 103 | Excellent | 10 | 62 | 60 |
| | | 1 | Soluble | Insoluble | 103 | Excellent | 10 | 62 | 20 |
| | | 2 | Soluble | Insoluble | 105 | Excellent | 10 | 62 | 50 |
| Example 24 | 2-4 | 0.1 | Soluble | Insoluble | 105 | Excellent | 10 | 63 | 20 |
| | | 1 | Soluble | Insoluble | 102 | Excellent | 10 | 62 | 10 |
| | | 2 | Soluble | Insoluble | 103 | Excellent | 10 | 63 | 20 |
| Example 25 | 2-5 | 0.1 | Soluble | Insoluble | 102 | Excellent | 10 | 63 | 20 |
| | | 1 | Soluble | Insoluble | 103 | Excellent | 10 | 62 | 10 |
| | | 2 | Soluble | Insoluble | 101 | Excellent | 10 | 62 | 10 |
| Example 26 | 2-6 | 0.1 | Soluble | Insoluble | 103 | Excellent | 10 | 63 | 50 |
| | | 1 | Soluble | Insoluble | 105 | Excellent | 10 | 62 | 30 |
| | | 2 | Soluble | Insoluble | 105 | Excellent | 10 | 62 | 30 |
| Example 27 | 2-7 | 0.1 | Soluble | Insoluble | 104 | Excellent | 10 | 62 | 30 |
| | | 1 | Soluble | Insoluble | 105 | Excellent | 10 | 62 | 20 |
| | | 2 | Soluble | Insoluble | 103 | Excellent | 10 | 62 | 10 |
| Example 28 | 2-8 | 0.1 | Soluble | Insoluble | 103 | Excellent | 10 | 64 | 60 |
| | | 1 | Soluble | Insoluble | 101 | Excellent | 10 | 63 | 30 |
| | | 2 | Soluble | Insoluble | 102 | Excellent | 10 | 63 | 40 |
| Example 29 | 2-9 | 0.1 | Soluble | Insoluble | 103 | Excellent | 10 | 63 | 50 |
| | | 1 | Soluble | Insoluble | 103 | Excellent | 10 | 62 | 20 |
| | | 2 | Soluble | Insoluble | 102 | Excellent | 10 | 62 | 30 |
| Example 30 | 2-10 | 0.1 | Soluble | Insoluble | 104 | Excellent | 10 | 63 | 40 |
| | | 1 | Soluble | Insoluble | 105 | Excellent | 10 | 62 | 20 |
| | | 2 | Soluble | Insoluble | 103 | Excellent | 10 | 62 | 20 |
| Comparative | Comparative 2-1 | 0.1 | Soluble | Insoluble | 103 | Excellent | 10 | 62 | 110 |
| Example 7 | | 1 | Soluble | Insoluble | 103 | Excellent | 10 | 63 | 120 |
| | | 2 | Soluble | Insoluble | 102 | Excellent | 10 | 63 | 120 |
| Comparative | Comparative 2-2 | 0.1 | Soluble | Insoluble | 103 | Excellent | 10 | 63 | 110 |
| Example 8 | | 1 | Soluble | Insoluble | 105 | Excellent | 10 | 62 | 120 |
| | | 2 | Soluble | Insoluble | 102 | Excellent | 10 | 62 | 120 |

As shown in Tables 2 and 3, the evaluation of the developer solubility shows that the banks of the examples and the comparative examples each correspond to a negative resist in which only the unexposed portions are soluble, and the evaluation of the bank properties shows that the banks of the examples and the comparative examples exhibited comparable sensitivity and had “Excellent” resolution as the 5 μm line-and-space pattern of the mask was transferred with good resolution without visible line-edge roughness. Moreover, the exposed portions showed sufficient values of anisole repellency. In other words, it was found from these evaluations that the surface modifiers of the examples and the comparative examples had only a small impact on the banks. Meanwhile, the banks of the comparative examples had a surface roughness of about 100 nm or more at the exposed portions (the upper portions of the banks), whereas the banks of the examples had a surface roughness of 10 to 70 nm, demonstrating that the examples were significantly better than the comparative examples.

The present application claims priority under the Paris Convention and the law of the designated state to Japanese Patent Application No. 2021-023616 filed on Feb. 17, 2021, the entire contents of which are hereby incorporated by reference.

1. A surface modifier, comprising a fluororesin (A) having a structure represented by the following formula (1): 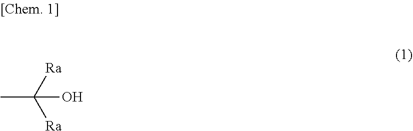
wherein each Ra independently represents a C1-C6 linear, C3-C6 branched, or C3-C6 cyclic alkyl group or a fluorine atom, and any number of hydrogen atoms in the alkyl group are replaced with fluorine atoms.

2. The surface modifier according to claim 1,
wherein an amount of the structure of formula (1) in the fluororesin (A) is at least 50 mol % but not more than 300 mol % relative to 100 mol % of a total amount of repeating units constituting the fluororesin (A).

3. The surface modifier according to claim 1,
wherein the fluororesin (A) has a weight average molecular weight of at least 5,000 but not more than 40,000.

4. The surface modifier according to claim 1,
wherein Ra in formula (1) is a trifluoromethyl group.

5. A photosensitive resin composition, comprising:
the surface modifier according to claim 1;
a fluororesin (B) having a crosslinking site;
a solvent; and
a photopolymerization initiator.

6. The photosensitive resin composition according to claim 5,
wherein an amount of the fluororesin (A) is at least 0.1 mass % but not more than 2.5 mass % relative to total solids of the photosensitive resin composition.

7. The photosensitive resin composition according to claim 5, further comprising at least one of an ethylenically unsaturated compound (C) or an alkali-soluble resin (D).

8. The photosensitive resin composition according to claim 5, further comprising at least one selected from the group consisting of a photo-radical sensitizer (E), a chain transfer agent (F), an ultraviolet absorber (G), and a polymerization inhibitor (H).

9. The photosensitive resin composition according to claim 5, which is for use to form a partition wall.

10. A cured product, obtained by curing the photosensitive resin composition according to claim 5.

11. The cured product according to claim 10, which is a partition wall.

12. A display, comprising a luminescent element including:
a partition wall obtained by curing the photosensitive resin composition according to claim 5; and
a luminescent layer or a wavelength conversion layer placed in a region partitioned by the partition wall.

13. The display according to claim 12, which is an organic EL display or a quantum dot display.

14. A method of modifying a surface of a molded article, the method comprising a fluororesin (A) having a structure represented by the following formula (1): 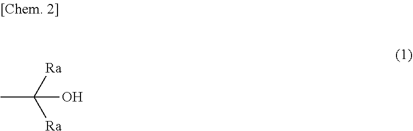
wherein each Ra independently represents a C1-C6 linear, C3-C6 branched, or C3-C6 cyclic alkyl group or a fluorine atom, and any number of hydrogen atoms in the alkyl group are replaced with fluorine atoms.

15. Use of a fluororesin (A) having a structure represented by the following formula (1) for modifying a surface of a molded article: 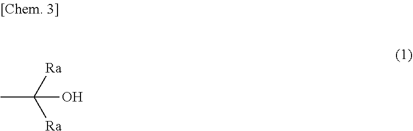
wherein each Ra independently represents a C1-C6 linear, C3-C6 branched, or C3-C6 cyclic alkyl group or a fluorine atom, and any number of hydrogen atoms in the alkyl group are replaced with fluorine atoms.
